(19) United States
(12) Patent Application Publication
(10) Pub. No.: US 2013/0025660 A1
(43) Pub. Date: Jan. 31, 2013

(54) PROCESSES FOR PHOTOVOLTAIC ABSORBERS WITH COMPOSITIONAL GRADIENTS

(71) Applicant: Precursor Energetics, Inc., Santa Clara, CA (US)

(72) Inventors: Kyle L. Fujdala, San Jose, CA (US); Zhongliang Zhu, San Jose, CA (US)

(73) Assignee: Precursor Energetics, Inc., Santa Clara, CA (US)

(21) Appl. No.: 13/631,911

(22) Filed: Sep. 29, 2012

Related U.S. Application Data
(63) Continuation-in-part of application No. 13/233,998, filed on Sep. 15, 2011.
(60) Provisional application No. 61/498,383, filed on Jun. 17, 2011.
(60) Provisional application No. 61/439,735, filed on Feb. 4, 2011.
(60) Provisional application No. 61/383,292, filed on Sep. 15, 2010.

(51) Int. Cl. H01L 31/18; H01L 31/065

(52) U.S. Cl. 136/255; 438/87; 257/E31.027

(57) ABSTRACT

Processes for making a photovoltaic absorber by depositing various layers of components on a substrate and converting the components into a thin film photovoltaic absorber material. Processes of this disclosure can be used to make a photovoltaic absorber having a concentration gradient of various atoms. CIGS thin film solar cells can be made.

### BACKGROUND

One way to produce a solar cell product involves forming a thin film of a photovoltaic absorber material on a substrate. For example, some commercial products have a thin layer of the material copper indium gallium diselenide, or “CIGS,” as the light absorber.

In making thin film photovoltaic absorber layers, precursor inks can be deposited on a substrate and transformed into the ultimate photovoltaic absorber layer. Photovoltaic absorber materials including CIGS can be made using molecular precursor inks and polymeric precursor inks which have been described in WO2011/017236 A2, WO2012/037382 A2, and PCT/US2012/028717.

Photovoltaic absorber materials in commercial products are generally made with a uniform composition so that they can be made with high purity and homogeneity. In most instances, the properties of the photovoltaic absorber material can be controlled only by changing its overall composition. In general, a problem in making products with photovoltaic absorber materials is that the properties of the photovoltaic absorber are not tuned by controlling composition within the physical dimensions of the product.

For example, it would be desirable to create gradients in the composition of the photovoltaic absorber material. Compositional gradients could be used to control the properties of the absorber.

One problem in creating photovoltaic absorber materials with compositional gradients is that diffusion or transport of atoms during the manufacturing process, especially during the annealing stage, make it difficult to create a well-defined gradient with controlled composition.

There is a general need for processes to make thin film photovoltaic materials that have a gradient in the composition of a particular atom, such as a metal atom.

What is needed are photovoltaic absorber layers with controlled properties having compositional gradients.

### BRIEF SUMMARY

This invention relates to processes for preparing photovoltaic absorber materials for devices including thin film solar cells. More particularly, this invention relates to processes for making photovoltaic absorbers with compositional gradients.

Embodiments of this disclosure include the following:

A process for making a photovoltaic absorber on a substrate comprising:

(a) providing a substrate coated with an electrical contact layer;

(b) depositing one layer of a first precursor ink onto the substrate, wherein the ink has a first concentration of a Group 13 atom;

(c) heating the substrate, thereby converting the first precursor ink to a first film material on the substrate;

(d) repeating steps (b) and (c) from zero to twenty times, thereby creating a second film material on the substrate;

(e) annealing the substrate;

(f) repeating steps (b) and (c), wherein each repetition uses an additional precursor ink having a different concentration of the Group 13 atom as any of the earlier steps, thereby creating a third film material;

(g) annealing the third film material, thereby creating a final film material on the substrate having a concentration gradient for the Group 13 atom.

The process above, wherein any one or more of the ink layers is substantially free from alkali ions, or substantially free from sodium ions.

The process above, wherein the Group 13 atom is indium, gallium, or aluminum.

The process above, repeating steps (f) and (g).

The process above, wherein the Group 13 atom is Ga and the concentrations are each a percentage that Ga atoms represent of the total of In plus Ga atoms, Ga/(In+Ga).

The process above, wherein the percentage that Ga atoms represent of the total of In plus Ga atoms, Ga/(In+Ga), within the gradient varies from 0% to 100%.

The process above, wherein at least a portion of the gradient is a step-up gradient, a step-down gradient, a step-up-hold-step-down gradient, a step-down-hold-step-up gradient, a continuous gradient, a downhill gradient, an uphill gradient, a depletion layer gradient, an enrichment layer gradient, or any combination of the foregoing.

The process above, wherein at least a portion of the gradient has a steepness of 20% or greater per micrometer, wherein the percentage represents the increase or decrease in the concentration that Ga atoms represent of the total of In plus Ga atoms, Ga/(In+Ga).

The process above, wherein any of the precursor inks contains a CIGS polymeric precursor compound.

The process above, wherein any of the precursor inks contains a CIS, AIS, AIGS, CAIS, CAIGS, CIGAS, AIGAS or CAIGAS polymeric precursor compound.

The process above, wherein any of the precursor inks contains a compound having the empirical formula M^{B}(ER)₃, where M^{B} is Al, Ga, or In, E is S or Se, and R is selected from alkyl, aryl, heteroaryl, alkenyl, amido, and silyl.

The process above, wherein any of the precursor inks contains a compound having the empirical formula M^{A}(ER), where M^{A} is Cu, Ag, or Au, E is S or Se, and R is selected from alkyl, aryl, heteroaryl, alkenyl, amido, and silyl.

The process above, wherein any of the precursor inks contains from 0.01 to 2.0 atom percent sodium ions.

The process above, wherein the final film material on the substrate is a CIGS photovoltaic material.

The process above, wherein the final film material on the substrate is a CIS, AIS, AIGS, CAIS, CAIGS, CIGAS, AIGAS or CAIGAS material.

The process above, wherein the heating to convert the ink to the first film material is at a temperature of from 100° C. to 450° C.

The process above, wherein the annealing is at a temperature of from 450° C. to 650° C., or at a temperature of from 450° C. to 650° C. in the presence of selenium vapor.

The process above, wherein the depositing is done by spraying, spray coating, spray deposition, spray pyrolysis, printing, screen printing, inkjet printing, ink printing, stamp printing, transfer printing, pad printing, flexographic printing, gravure printing, contact printing, reverse printing, thermal printing, lithography, electrophotographic printing, electrodepositing, electroplating, electroless plating, bath deposition, coating, wet coating, dip coating spin coating, knife coating, roller coating, rod coating, slot die coating, meyerbar coating, lip direct coating, capillary coating, liquid deposition, solution deposition, layer-by-layer deposition, spin casting, solution casting, or combinations of any of the forgoing.

The process above, wherein the substrate is selected from the group of a semiconductor, a doped semiconductor, silicon, gallium arsenide, insulators, glass, molybdenum glass, silicon dioxide, titanium dioxide, zinc oxide, silicon nitride, a metal, a metal foil, molybdenum, aluminum, beryllium, cadmium, cerium, chromium, cobalt, copper, gallium, gold, lead, manganese, molybdenum, nickel, palladium, platinum, rhenium, rhodium, silver, stainless steel, steel, iron, strontium, tin, titanium, tungsten, zinc, zirconium, a metal alloy, a metal silicide, a metal carbide, a polymer, a plastic, a conductive polymer, a copolymer, a polymer blend, a polyethylene terephthalate, a polycarbonate, a polyester, a polyester film, a mylar, a polyvinyl fluoride, polyvinylidene fluoride, a polyethylene, a polyetherimide, a polyethersulfone, a polyetherketone, a polyimide, a polyvinylchloride, an acrylonitrile butadiene styrene polymer, a silicone, an epoxy, and combinations of any of the forgoing.

A photovoltaic absorber made by the process of claim 1.

A process for making a photovoltaic absorber layer on a substrate comprising:

(a) providing a substrate;

(b) forming a layer of a first material on the substrate, wherein the first material has a first concentration of a Group 13 atom and the first material contains alkali ions;

(c) forming a layer of a second material onto the first material, wherein the second material has a second concentration of a Group 13 atom that is the same or different from the first concentration, wherein the second material is substantially free from alkali ions.

The process above, wherein steps (b) and/or (c) are repeated one or more times in any order, wherein the additional layers have a concentration of the Group 13 the same or different as any of the previous layers.

The process above, wherein steps (b) and/or (c) are repeated one or more times in any order and any of the layers are annealed after being formed.

The process above, wherein steps (b) and (c) are repeated one or more times in any order, thereby forming two or more sodium-free layers.

The process above, wherein the first material is annealed before step (c).

The process above, wherein the second material is annealed after being formed.

The process above, wherein the Group 13 atom is indium, gallium, or aluminum.

The process above, wherein the alkali ions are sodium ions at a concentration of from 0.01 to 2.0 atom percent.

The process above, wherein the Group 13 atom is Ga and the concentrations are each a percentage that Ga atoms represent of the total of In plus Ga atoms, Ga/(In+Ga).

The process above, wherein at least a portion of the gradient is a step-up gradient, a step-down gradient, a step-up-hold-step-down gradient, a step-down-hold-step-up gradient, a continuous gradient, a downhill gradient, an uphill gradient, a depletion layer gradient, an enrichment layer gradient, or any combination of the foregoing.

The process above, wherein the Group 13 atom is Ga, the first, second and third materials contain In and Ga and not Al, and wherein at least a portion of the gradient is a step-up-hold-step-down or enrichment layer gradient in the concentration that Ga atoms represent of the total of In plus Ga atoms, Ga/(In+Ga).

The process above, wherein at least a portion of the gradient has a steepness of 20% or greater per micrometer, wherein the percentage represents the increase or decrease in the concentration that Ga atoms represent of the total of In plus Ga atoms, Ga/(In+Ga).

The process above, wherein the photovoltaic absorber material on the substrate is a CIGS photovoltaic material.

The process above, wherein the photovoltaic absorber material on the substrate is a CIS, AIS, AIGS, CAIS, CAIGS, CIGAS, AIGAS or CAIGAS material.

The process above, wherein any of the layers is annealed in the presence of selenium vapor.

The process above, wherein any one of the layers is formed by depositing an ink containing one or more polymeric precursor compounds.

The process above, wherein any one of the layers is formed by depositing an ink containing one or more compounds having the formula M^{B}(ER)₃, wherein M^{B} is In, Ga or Al, E is S or Se, and R is selected from alkyl, aryl, heteroaryl, alkenyl, amido, and silyl.

The process above, wherein any one of the layers is formed by depositing an ink containing one or more compounds having the formula M^{A}(ER), wherein M^{A} is Cu or Ag, E is S or Se, and R is selected from alkyl, aryl, heteroaryl, alkenyl, amido, and silyl.

The process above, wherein any one of the layers is formed by chemical vapor deposition, metal-organic chemical vapor deposition, plasma enhanced chemical vapor deposition, atomic layer deposition, plasma-enhanced atomic layer deposition, sputtering, RF sputtering, DC sputtering, magnetron sputtering, evaporation, co-evaporation, electron beam evaporation, laser ablation, or any combination of the foregoing.

The process above, wherein any of the layers is formed by spraying, spray coating, spray deposition, spray pyrolysis, printing, screen printing, inkjet printing, ink printing, stamp printing, transfer printing, pad printing, flexographic printing, gravure printing, contact printing, reverse printing, thermal printing, lithography, electrophotographic printing, electrodepositing, electroplating, electroless plating, bath deposition, coating, wet coating, dip coating spin coating, knife coating, roller coating, rod coating, slot die coating, meyerbar coating, lip direct coating, capillary coating, liquid deposition, solution deposition, layer-by-layer deposition, spin casting, solution casting, or combinations of any of the forgoing.

The process above, wherein the substrate is selected from the group of a semiconductor, a doped semiconductor, silicon, gallium arsenide, insulators, glass, molybdenum glass, silicon dioxide, titanium dioxide, zinc oxide, silicon nitride, a metal, a metal foil, molybdenum, aluminum, beryllium, cadmium, cerium, chromium, cobalt, copper, gallium, gold, lead, manganese, molybdenum, nickel, palladium, platinum, rhenium, rhodium, silver, stainless steel, steel, iron, strontium, tin, titanium, tungsten, zinc, zirconium, a metal alloy, a metal silicide, a metal carbide, a polymer, a plastic, a conductive polymer, a copolymer, a polymer blend, a polyethylene terephthalate, a polycarbonate, a polyester, a polyester film, a mylar, a polyvinyl fluoride, polyvinylidene fluoride, a polyethylene, a polyetherimide, a polyethersulfone, a polyetherketone, a polyimide, a polyvinylchloride, an acrylonitrile butadiene styrene polymer, a silicone, an epoxy, and combinations of any of the forgoing.

A photovoltaic absorber made by the process above.

A photovoltaic absorber comprising a thin film material on a substrate, wherein at least a portion of the thin film material has a gradient of the concentration of a Group 13 atom in a direction substantially normal to the substrate.

The photovoltaic absorber above, wherein the material is a CIGS material.

The photovoltaic absorber above, wherein the material is a CIS, AIS, AIGS, CAIS, CAIGS, CIGAS, AIGAS or CAIGAS material.

The photovoltaic absorber above, wherein the Group 13 atom is indium, gallium, or aluminum.

The photovoltaic absorber above, wherein the Group 13 atom is Ga, the material contains In and Ga and not Al, and the concentrations are each a percentage that Ga atoms represent of the total of In plus Ga atoms, Ga/(In+Ga).

The photovoltaic absorber above, wherein at least a portion of the gradient is a step-up gradient, a step-down gradient, a step-up-hold-step-down gradient, a step-down-hold-step-up gradient, a continuous gradient, a downhill gradient, an uphill gradient, a depletion layer gradient, an enrichment layer gradient, or any combination of the foregoing.

The photovoltaic absorber above, wherein the Group 13 atom is Ga, the material contains In and Ga and not Al, and wherein at least a portion of the gradient is a step-up-hold-step-down or enrichment layer gradient in the concentration that Ga atoms represent of the total of In plus Ga atoms, Ga/(In+Ga).

The photovoltaic absorber above, wherein at least a portion of the gradient has a steepness of 20% or greater per micrometer, wherein the percentage represents the increase or decrease in the concentration that Ga atoms represent of the total of In plus Ga atoms, Ga/(In+Ga).

This summary, taken along with the detailed description of the invention, as well as the figures, the appended examples and claims, as a whole, encompass the disclosure of the invention.

### BRIEF DESCRIPTION OF THE DRAWINGS

FIG. 1 shows a chart of a compositional gradient of gallium in a material of this disclosure as measured by SIMS. The vertical axis shows the concentration of gallium as a percentage that Ga atoms represent of the total of In plus Ga atoms, Ga/(In+Ga). The horizontal axis represents distance (d) from the substrate increasing to the left. The chart of FIG. 1 shows a step-down gradient of gallium concentration as the distance from the substrate increases.

FIG. 2 shows a chart of a compositional gradient of gallium in a material of this disclosure as measured by SIMS. The vertical axis shows the concentration of gallium as a percentage that Ga atoms represent of the total of In plus Ga atoms, Ga/(In+Ga). The horizontal axis represents distance (d) from the substrate increasing to the left. The chart of FIG. 2 shows a continuous downhill gradient of gallium concentration as the distance from the substrate increases.

FIG. 3 shows a chart of a compositional gradient of gallium in a material of this disclosure as measured by SIMS. The vertical axis shows the concentration of gallium as a percentage that Ga atoms represent of the total of In plus Ga atoms, Ga/(In+Ga). The horizontal axis represents distance (d) from the substrate increasing to the left. The chart of FIG. 3 shows a continuous downhill gradient of gallium concentration as the distance from the substrate increases.

FIG. 4 shows a chart of a compositional gradient of gallium in a material of this disclosure as measured by SIMS. The vertical axis shows the concentration of gallium as a percentage that Ga atoms represent of the total of In plus Ga atoms, Ga/(In+Ga). The horizontal axis represents distance (d) from the substrate increasing to the left. The chart of FIG. 4 shows a continuous downhill gradient of gallium concentration as the distance from the substrate increases.

FIG. 5 shows a chart of a compositional gradient of gallium in a material of this disclosure as measured by SIMS. The vertical axis shows the concentration of gallium as a percentage that Ga atoms represent of the total of In plus Ga atoms, Ga/(In+Ga). The horizontal axis represents distance (d) from the substrate increasing to the left. The chart of FIG. 5 shows a continuous downhill gradient of gallium concentration as the distance from the substrate increases.

FIG. 6 shows a chart of a compositional gradient of gallium in a material of this disclosure as measured by SIMS. The vertical axis shows the concentration of gallium as a percentage that Ga atoms represent of the total of In plus Ga atoms, Ga/(In+Ga). The horizontal axis represents distance (d) from the substrate increasing to the left. The chart of FIG. 6 shows a continuous downhill gradient of gallium concentration as the distance from the substrate increases.

FIG. 7 shows a schematic representation of compositional continuous gradients in a layer of a photovoltaic material on a substrate. The vertical axis represents concentration of an atom (C). The horizontal axis represents distance from the substrate (d). In FIG. 7, from top to bottom, the compositional continuous gradients are a downhill gradient, an uphill gradient, a depletion layer gradient, and an enrichment layer gradient.

FIG. 8 shows a schematic representation of compositional continuous gradients in a layer of a photovoltaic material on a substrate. The vertical axis represents concentration of an atom (C). The horizontal axis represents distance from the substrate (d). In FIG. 8, from top to bottom, the compositional continuous gradients are an enrichment layer gradient, an enrichment layer gradient, a depletion layer gradient, and a depletion layer gradient.

FIG. 9 shows a schematic representation of compositional step gradients in a layer of a photovoltaic material on a substrate. The vertical axis represents concentration of an atom (C). The horizontal axis represents distance from the substrate (d). In FIG. 9, from top to bottom, the compositional step gradients are a step-down gradient, a step-up gradient, a step-down-hold-step-up gradient, and a step-up-hold-step-down gradient.

FIG. 10 shows a schematic representation of compositional step gradients in a layer of a photovoltaic material on a substrate. The vertical axis represents concentration of an atom (C). The horizontal axis represents distance from the substrate (d). In FIG. 10, from top to bottom, the compositional step gradients are a step-up-hold-step-down gradient, a step-up-hold-step-down gradient, a step-down-hold-step-up gradient, and a step-down-hold-step-up gradient.

FIG. 11 shows a schematic representation of steps of a process to make a photovoltaic material on a substrate 100. Each layer 402, 404, 406, 408, 410 and 412 represents a precursor component used in forming the photovoltaic material. The concentration of a particular atom, such as gallium, may be different in each of the layers 402, 404, 406, 408, 410 and 412. In a process of this invention, each of the individual layers 402, 404, 406, 408, 410 and 412 is annealed before the succeeding layer is deposited.

FIG. 12 shows a schematic representation of steps of a process to make a photovoltaic material on a substrate 100. Each of the layers 502 and 506 represents a precursor component used in forming the photovoltaic material, where the precursor component contains alkali ions. Layer 504 represents a precursor component that is substantially free from alkali ions. The concentration of a particular atom, such as gallium, may be different in each of the layers 502, 504 and 506. In a process of this invention, the individual layers 502, 504 and 506 can be annealed in one step at the same time.

FIG. 13 shows a schematic representation of steps of a process to make a photovoltaic material on a substrate 100. Each of the layers 602, 604, 606, 608, 610 and 612 represents a precursor component used in forming the photovoltaic material. In some of the layers 602, 604, 606, 608, 610 and 612 the precursor component contains alkali ions. Certain layers among the layers 602, 604, 606, 608, 610 and 612 may have a precursor component that is substantially free from alkali ions. The concentration of a particular atom, such as gallium, may be different in each of the layers 602, 604, 606, 608, 610 and 612. In a process of this invention, the individual layers 602, 604, 606, 608, 610 and 612 can be annealed in one step at the same time.

### DETAILED DESCRIPTION

This disclosure provides compositions and processes for photovoltaic absorber layers for photovoltaic and electrooptical devices.

Aspects of this invention provide processes and compositions for photovoltaic materials and photovoltaic absorbers on a substrate having a gradient in concentration with respect to the distance from the surface of the substrate.

Among other things, the compositions and processes of this disclosure can be used for making solar cells having high efficiencies for conversion of light.

In certain aspects, this invention can provide control over the transport or diffusion of atoms during a process to make photovoltaic materials and photovoltaic absorbers.

In one aspect, this disclosure provides processes for making a photovoltaic absorber layer by depositing layers of various components on a substrate and converting the components to a material. A component can be, for example, an element, a compound, a precursor, a molecular precursor, a polymeric precursor, or a material composition.

In certain aspects, a photovoltaic absorber layer may be fabricated using layers of polymeric precursor compounds. Polymeric precursor compounds can contain all the elements needed for the photovoltaic absorber material composition. Polymeric precursor compounds can be deposited on a substrate and converted to a photovoltaic material. For example, polymeric precursors for photovoltaic materials are described in WO2011/017235, WO2011/017236, WO2011/017237, and WO2011/017238, each of which is hereby incorporated by reference in its entirety for all purposes.

In further aspects, this disclosure provides processes for making photovoltaic materials by depositing layers of components on a substrate. The composition of each of the deposited layers can be different. The stoichiometry of the layers can be varied by using component precursor compounds having different, yet fixed stoichiometry.

In some embodiments, the stoichiometry of layers can be varied by using one or more polymeric precursor compounds that can have an arbitrary, predetermined stoichiometry.

In certain embodiments, the variation of the stoichiometry of the layers of precursors on a substrate can form a gradient in the composition of one or more elements with respect to distance from the surface of the substrate.

For example, the processes and compositions of this invention can be used to make photovoltaic absorbers having a gradient in the concentration of a metal atom, or transition metal atom. In some embodiments, the processes and compositions of this invention can be used to make photovoltaic absorbers having a gradient in the concentration of atoms of Group 11, Group 13, or Group 16.

Photovoltaic Absorbers with Compositional Gradients

In some embodiments, this invention provides photovoltaic absorbers having compositional gradients.

In certain embodiments, a compositional gradients in a photovoltaic absorber may be a continuous gradient.

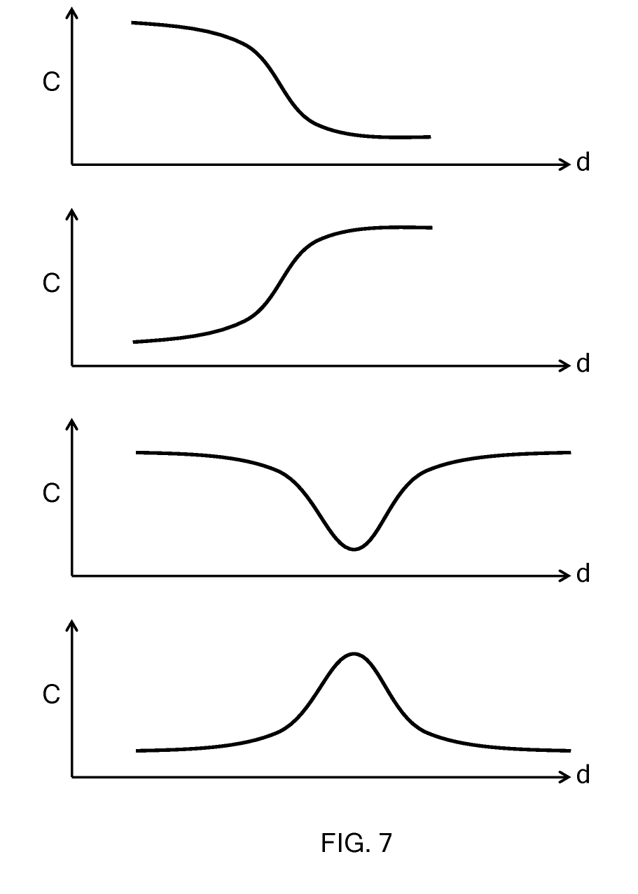

For example, FIG. 7 shows a schematic representation of the compositional structure of a photovoltaic absorber having a continuous gradient. The photovoltaic absorber having a non-uniform composition or grading of composition can be created on a substrate. In FIG. 7, the vertical axis represents concentration of an atom (C). The horizontal axis represents distance (d) from the substrate. The continuous curve represents a continuously varying concentration of an atom as the distance from the substrate changes.

In the examples of FIGS. 7-10, the distance (d) from the substrate can be taken as increasing toward the left, or as increasing toward the right, so that the sense of the gradient would be reversed, e.g. uphill would be downhill.

For example, in FIG. 7, from top to bottom, the compositional continuous gradients are a downhill gradient, an uphill gradient, a depletion layer gradient, and an enrichment layer gradient. For the uphill gradient, for example, at least in some portion of the photovoltaic absorber the concentration of an atom increases. For an enrichment layer gradient, at least in some portion of the photovoltaic absorber the concentration of an atom increases, reaches a maximum, and decreases again as the distance from the substrate increases. The circumstances are reversed for the downhill and depletion layer gradients, respectively.

A continuous compositional gradient in a photovoltaic absorber may be created by a process described below.

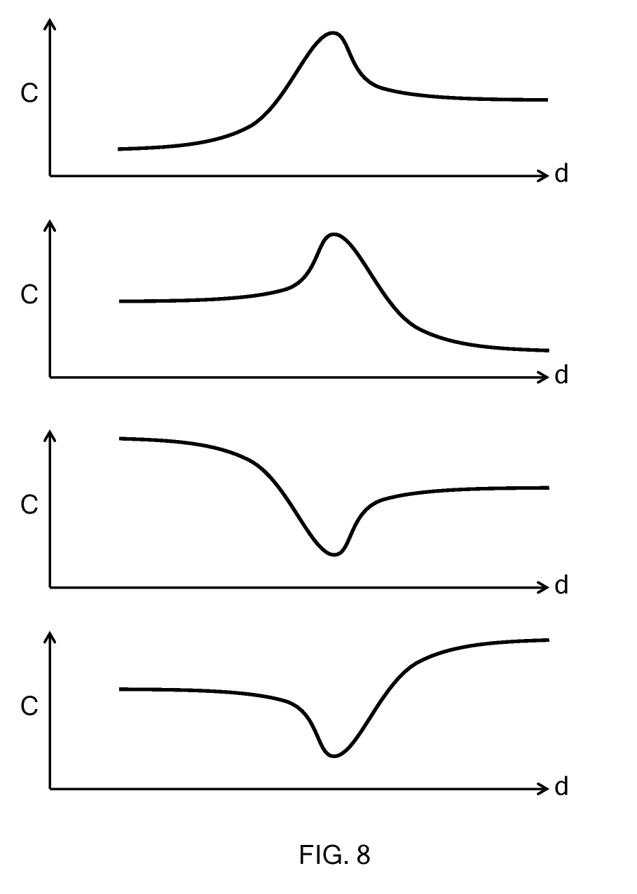

FIG. 8 shows a schematic representation of compositional continuous gradients in a layer of a photovoltaic material on a substrate. In FIG. 8, from top to bottom, the compositional continuous gradients are an enrichment layer gradient, an enrichment layer gradient, a depletion layer gradient, and a depletion layer gradient.

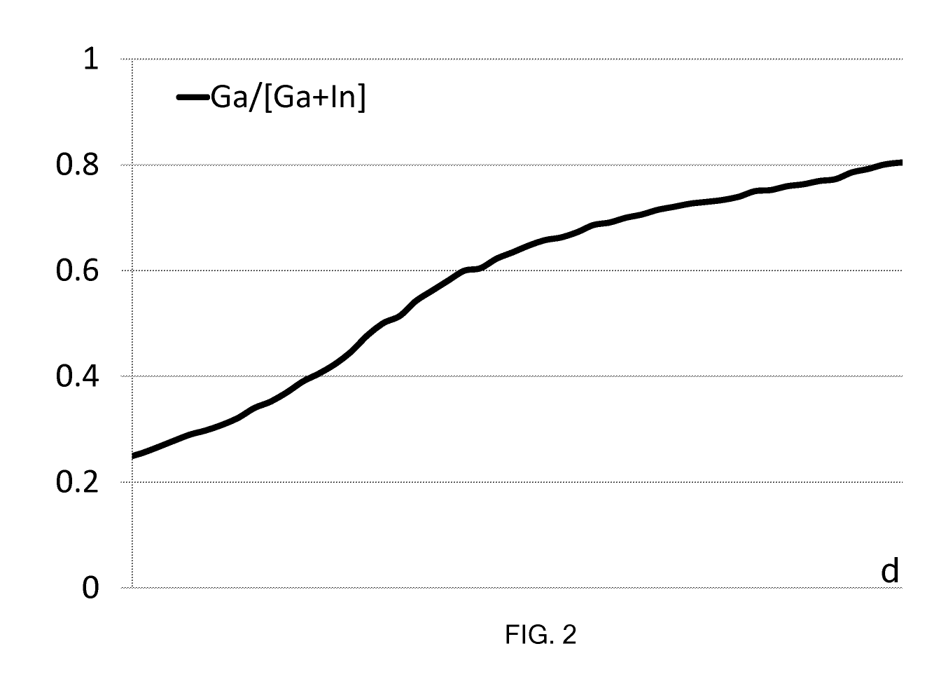

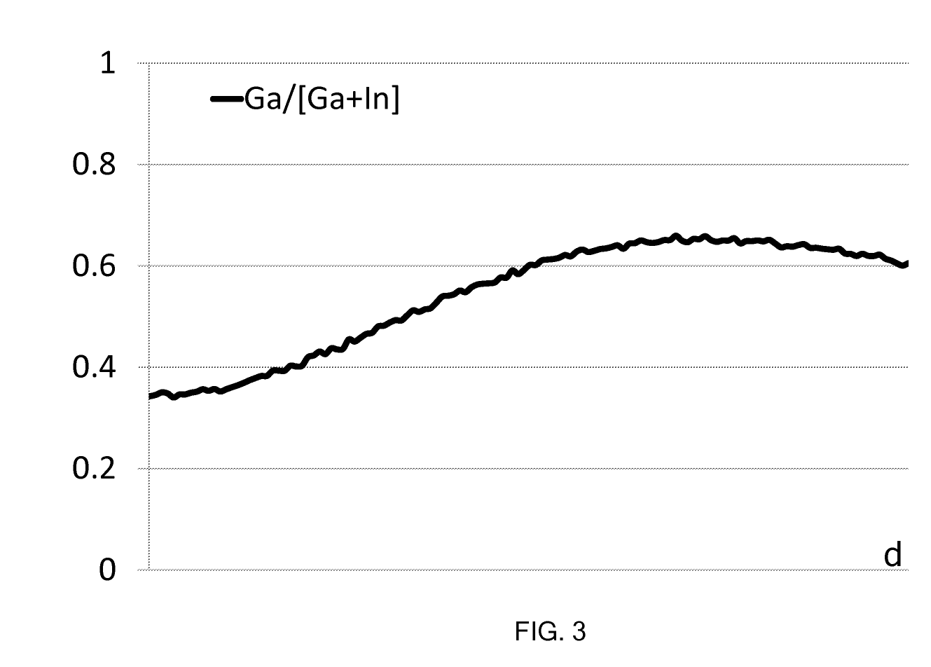

FIGS. 2 and 3 show that the beginning and ending levels of the concentration of an atom in an enrichment layer gradient or a depletion layer gradient may be the same or different.

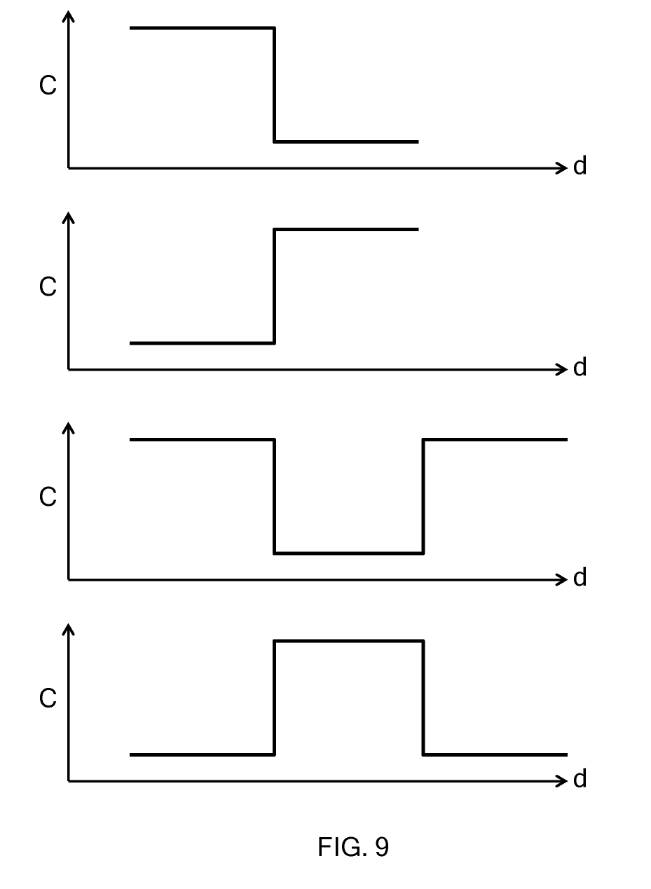

FIG. 9 shows a schematic representation of compositional step gradients in a layer of a photovoltaic material on a substrate. In FIG. 9, from top to bottom, the compositional step gradients are a step-down gradient, a step-up gradient, a step-down-hold-step-up gradient, and a step-up-hold-step-down gradient.

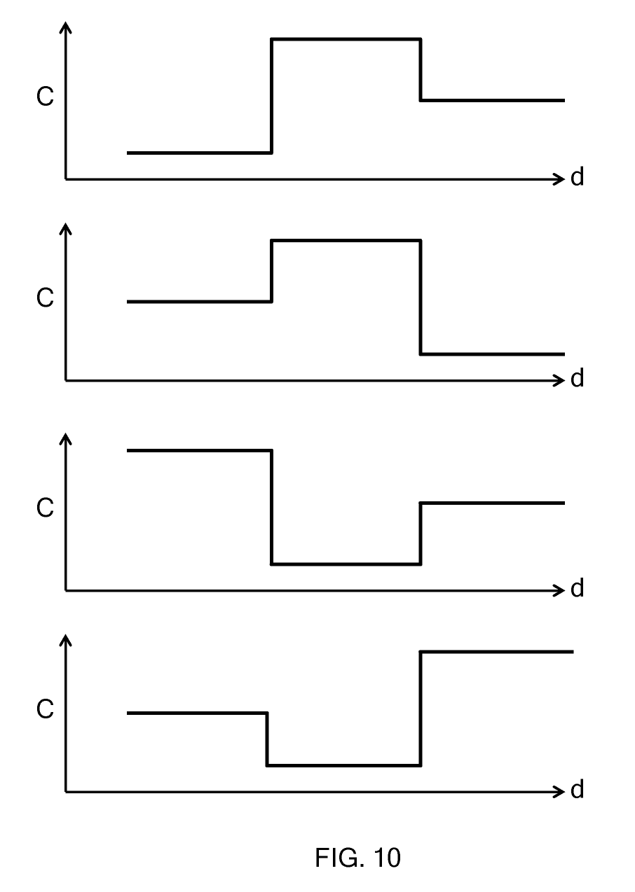

FIG. 10 shows a schematic representation of compositional step gradients in a layer of a photovoltaic material on a substrate. In FIG. 10, from top to bottom, the compositional step gradients are a step-up-hold-step-down gradient, a step-up-hold-step-down gradient, a step-down-hold-step-up gradient, and a step-down-hold-step-up gradient.

The distance from the substrate refers to a direction substantially normal to the surface of the substrate. When the substrate is not a flat surface or article, then the distance from the substrate refers to a direction substantially normal to the local surface of the substrate.

A gradient can be made in a photovoltaic layer on a substrate within a particular or pre-determined area of the substrate, or in a patterned area of a substrate surface.

Precursors for Photovoltaic Absorbers with Compositional Gradients

In some aspects, this invention provides methods for making photovoltaic absorbers with compositional gradients using precursor compounds. The precursor compounds are used to form layers on a substrate, which are ultimately converted to a material composition. The material composition can be a photovoltaic absorber with a compositional gradient.

This invention provides processes and compositions for making a photovoltaic absorber with a compositional gradient by advantageously controlling both the compositional gradient stoichiometry as well as the diffusion or transport of atoms during the process.

The layers of precursors on a substrate can be converted to a material composition by applying energy to the layered substrate article. Energy can be applied using heat, light, or radiation, or by applying chemical energy.

In some embodiments, a layer may be converted to a material individually, before the deposition of a succeeding layer. In certain embodiments, a group of layers can be converted at the same time.

The precursor compounds may be polymeric precursor compounds.

For example, a precursor compound may have the empirical formula (Cu)ᵤ(M^{B1}_{1-y-t}M^{B2}_{y}M^{B3}ₜ)ᵥ((S_{1-z}Se_{z})R)_{w}, wherein y is from 0 to 1, t is from 0 to 1, the sum of y plus t is from 0 to 1, z is from 0 to 1, u is 0.5 to 1.5, v is 0.5 to 1.5, w is from 2 to 6, and R represents R groups, of which there are w in number, independently selected from alkyl, aryl, heteroaryl, alkenyl, amido, silyl, and inorganic and organic groups. In some embodiments, R is alkyl.

For example, a precursor compound may have the empirical formula (Cu₁₋ₓAgₓ)ᵤ(M^{B1}_{1-y-t}M^{B2}_{y}M^{B3}ₜ)ᵥ((S_{1-z}Se_{z})R)_{w}, wherein x is from 0 to 1, y is from 0 to 1, t is from 0 to 1, the sum of y plus t is from 0 to 1, z is from 0 to 1, u is from 0.5 to 2.0, v is from 0.5 to 2.0, w is from 2 to 6, and R represents R groups, of which there are w in number, independently selected from alkyl, aryl, heteroaryl, alkenyl, amido, silyl, and inorganic and organic groups. In some embodiments, R is alkyl. In some embodiments, v is one, and u is 0.60, 0.61, 0.62, 0.63, 0.64, 0.65, 0.66, 0.67, 0.68, 0.69, 0.70, 0.71, 0.72, 0.73, 0.74, 0.75, 0.76, 0.77, 0.78, 0.79, 0.80, 0.81, 0.82, 0.83, 0.84, 0.85, 0.86, 0.87, 0.88, 0.89, 0.90, 0.91, 0.92, 0.93, 0.94, 0.95, 0.96, 0.97, 0.98, 0.99, or 1. In some embodiments, v is one, and u is 1.1, or 1.2, or 1.3, or 1.4, or 1.5, or 1.6, or 1.7, or 1.8, or 1.9, or 2.0, or 2.1, or 2.2, or 2.3, or 2.4, or 2.5, or 2.6, or 2.7, or 2.8, or 2.9, or 3.0, or 3.1, or 3.2, or 3.3, or 3.4, or 3.5, or 3.6, or 3.7, or 3.8, or 3.9, or 4.0. In some embodiments, y is 0.001, or 0.002. In some embodiments, t is 0.001, or 0.002. In some embodiments, the sum of y plus t is 0.001, or 0.002, or 0.003, or 0.004. In some embodiments, x is 0.005, 0.01, 0.02, 0.03, 0.04, 0.05, 0.1, or 0.15.

In certain embodiments, the precursor compounds can have the empirical formula M^{B}(ER)₃, where M^{B} is Al, Ga, or In, and R is selected from alkyl, aryl, heteroaryl, alkenyl, amido, silyl, and inorganic and organic groups. In some embodiments, R is alkyl.

In some embodiments, the precursor compounds can have the empirical formula M^{A}(ER), where M^{A} is Cu, Ag, or Au, and R is selected from alkyl, aryl, heteroaryl, alkenyl, amido, silyl, and inorganic and organic groups. In some embodiments, R is alkyl.

Precursor compounds of this disclosure may be used to make a photovoltaic layer or material having any arbitrary, predetermined or desired stoichiometry. Utilizing the advantageous properties of the precursor compounds, it has been found that photovoltaic materials of this disclosure can be made with a compositional gradient.

Photovoltaic materials of this disclosure include CIS, CIGS, AIS, AIGS, CAIS, CAIGS, CIGAS, AIGAS and CAIGAS materials, including materials that are enriched or deficient in the quantity of a certain atom.

Following the synthesis of the precursor compounds, the compounds can be coated, sprayed, deposited, or printed onto substrates and formed into a photovoltaic absorber material.

For polymeric precursor compounds, the photovoltaic absorber material can be prepared by one of a range of processes disclosed herein. When prepared from one or more polymeric precursor compounds, a photovoltaic absorber material can retain the predetermined stoichiometry of the metal atoms of the polymeric precursor compounds. The processes disclosed herein therefore allow a photovoltaic absorber material or layer having a specific target, or predetermined stoichiometry to be made using precursors of this invention. The processes disclosed further allow the photovoltaic absorber material to have a compositional gradient by utilizing polymeric precursor compounds in different or successive layers having different stoichiometries.

Among other advantages, the polymeric compounds, compositions, materials and methods of this invention can provide a precursor compound for making semiconductor and optoelectronic materials, including CIS, CIGS, AIS, AIGS, CAIS, CAIGS, CIGAS, AIGAS and CAIGAS absorber layers for solar cells and other devices. In some embodiments, the source precursor compounds of this invention can be used alone, without other compounds, to prepare a layer from which CIS, CIGS, AIS, AIGS, CAIS, CAIGS, CIGAS, AIGAS and CAIGAS and other materials can be made. Polymeric precursor compounds may also be used in a mixture with additional compounds to control stoichiometry of a layer or material.

As used herein, converting refers to a process, for example a heating or thermal process, which converts one or more precursor compounds into a semiconductor material.

As used herein, annealing refers to a process, for example a heating or thermal process, which transforms a semiconductor material from one form into another form.

Polymeric precursors can advantageously form a thin, uniform film on a substrate.

In general, the structure and properties of the polymeric compounds, compositions, and materials of this invention provide advantages in making photovoltaic layers and devices regardless of the morphology, architecture, or manner of fabrication of the devices.

### Compositions of Photovoltaic Absorbers Having a Gradient in Concentration

Aspects of this invention provide compositions of photovoltaic materials and photovoltaic absorber layers on a substrate having a gradient in concentration with respect to the distance from the surface of the substrate.

Embodiments of this invention can advantageously provide processes for making a photovoltaic absorber with a compositional gradient, wherein the diffusion or transport of atoms during the process are controlled so that a well-defined compositional gradient can be formed.

FIG. 7 shows a schematic representation of compositional step gradients of this disclosure that can be made in a layer of a photovoltaic material on a substrate. In FIG. 7, the vertical axis represents the concentration of an atom (C). The atom can be any metal atom or transitional metal atom, including atoms of Groups 11 and 13. The horizontal axis represents distance from the substrate (d). The substrate can have any shape, so the distance d is taken in a direction approximately normal to the local surface of the substrate. In FIG. 7, from top to bottom, respectively, the compositional step gradients are a step-down gradient, a step-up gradient, a step-down-hold-step-up gradient, and a step-up-hold-step-down gradient. Any combination of step gradients can also be made.

After various steps of a process of this disclosure, the compositional gradient of a photovoltaic material or photovoltaic absorber layer on a substrate may be a continuous gradient.

FIG. 8 shows a schematic representation of compositional continuous gradients of this disclosure that can be made in a layer of a photovoltaic material on a substrate. In FIG. 8, from top to bottom, respectively, the compositional continuous gradients are a downhill gradient, an uphill gradient, a depletion layer gradient, and an enrichment layer gradient.

Processes for Photovoltaic Absorber Layers with Compositional Gradients

Aspects of this invention provide processes for making photovoltaic materials and photovoltaic absorber layers on a substrate having a gradient in concentration with respect to the distance from the surface of the substrate.

Embodiments of this invention can advantageously control the diffusion or transport of atoms during a process for making a photovoltaic absorber material.

In some embodiments, a well-defined compositional gradient can be formed by preventing or suppressing the diffusion or transport of atoms during the process.

In certain embodiments, a well-defined compositional gradient can be formed by blocking the diffusion or transport of atoms during the process.

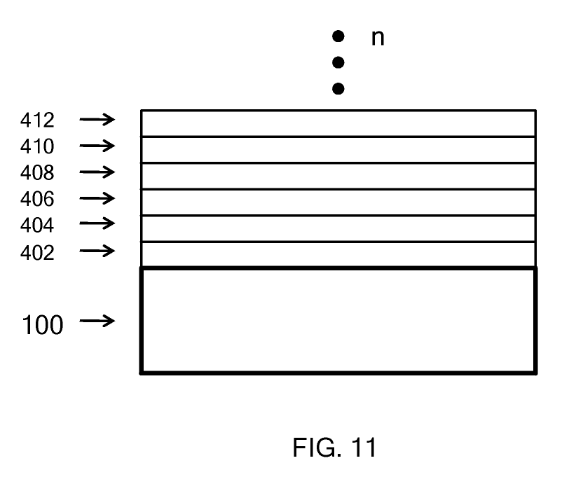

FIG. 11 shows a schematic representation of steps of a process to make a photovoltaic absorber material layer on a substrate 100. Each layer 402, 404, 406, 408, 410 and 412 represents a precursor component that is deposited on the substrate and used in forming the photovoltaic absorber material layer. FIG. 11 shows the sequence in which the layers are deposited. The concentration of a particular atom, for example gallium, may be different in each of the layers 402, 404, 406, 408, 410 and 412. In a process of this invention, each of the individual layers 402, 404, 406, 408, 410 and 412 may be annealed before the next layer is deposited. For example, layer 402 can be deposited and annealed before layer 404 is deposited, and layer 404 can be annealed before layer 406 is deposited, and so forth.

Embodiments of this invention can provide a process for making a photovoltaic absorber material having a well-defined compositional gradient by annealing individual layers of a composition, which may block the diffusion or transport of certain atoms.

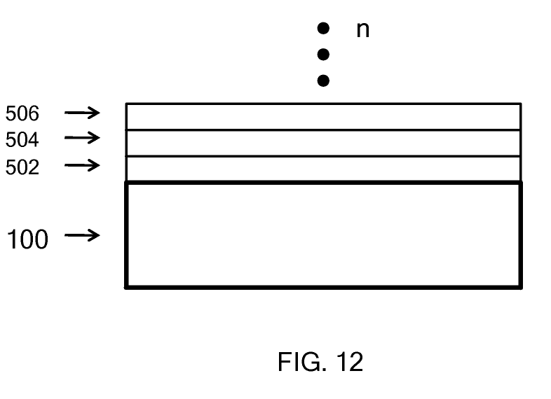

FIG. 12 shows a schematic representation of steps of a process to make a photovoltaic absorber material layer on a substrate 100. Each of the layers 502, 504 and 506 represents a precursor component that is deposited on the substrate and used in forming the photovoltaic absorber material layer. Layers 502 and 506 each represent a precursor component that is deposited on the substrate and contains alkali ions. Layer 504 represents a precursor component that is deposited on the substrate and is substantially free from alkali ions. Layer 504 therefore represents a precursor component that is deposited on the substrate to make an alkali free zone. The concentration of a particular atom, for example gallium, may be different in each of the layers 502, 504 and 506. In a process of this invention, the individual layers 502, 504 and 506 may be annealed in one step at the same time. Alternatively, each of the individual layers 502, 504 and 506 may be annealed before the next layer is deposited.

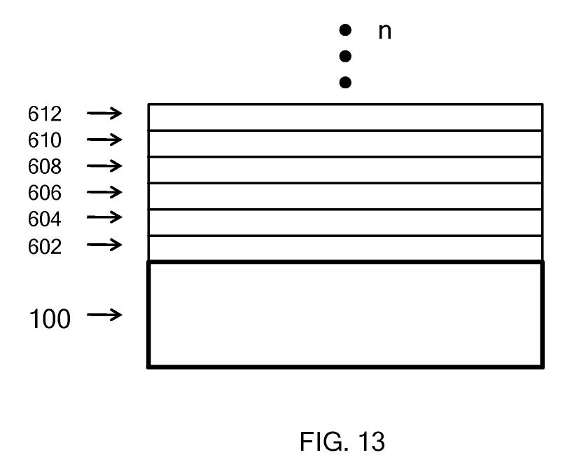

FIG. 13 shows a schematic representation of steps of a process to make a photovoltaic absorber material layer on a substrate 100. As shown in FIG. 13, in some aspects, a layered substrate can have any number of layers, n, deposited on the substrate. Each of the layers 602, 604, 606, 608, 610 and 612 represents a precursor component that is deposited on the substrate and used in forming the photovoltaic absorber material layer. Any of the layers 602, 604, 606, 608, 610 and 612 may be a precursor component that contains alkali ions. Certain layers among the layers 602, 604, 606, 608, 610 and 612 may be a precursor component that is substantially free from alkali ions and forms an alkali free zone. The concentration of a particular atom, for example gallium, may be different in each of the layers 602, 604, 606, 608, 610 and 612. In a process of this invention, the individual layers 602, 604, 606, 608, 610 and 612 can be annealed in one step at the same time, or alternatively, each individual layer may be annealed before the next layer is deposited.

Embodiments of this invention can provide a process for making a photovoltaic absorber material having a well-defined compositional gradient by providing alkali free zones during the process that can prevent or suppress the diffusion or transport of certain atoms. Alkali free zones may be formed between layers or zones that contain significant amounts of alkali ions.

Each step of heating can transform any and all layers present on the substrate into a material layer.

Any of the layers can be heated to form a thin film material before the deposition of the next layer.

Any of the layers may be deficient or enriched in the quantity of a Group 11 atom, or of a Group 13 atom.

Any of the layers may contain sodium ions which can be introduced into an ink containing the precursor compounds.

In some aspects, a layered substrate can be made by depositing a layer of one or more precursor compounds, such as one or more polymeric precursor compounds, onto the substrate. The layer of the precursor compounds can be a single thin layer of the compounds, or a plurality of layers of the compound.

A layer may have a thickness after heating of from about 20 to 5000 nanometers. In some embodiments, a layer may have a thickness after heating of 10, 20, 50, 75, 100, 125, 150, 175, 200, 225, 250, 275, 300, 350, 400, 450, 500, 750, 1000 or 1500 nanometers.

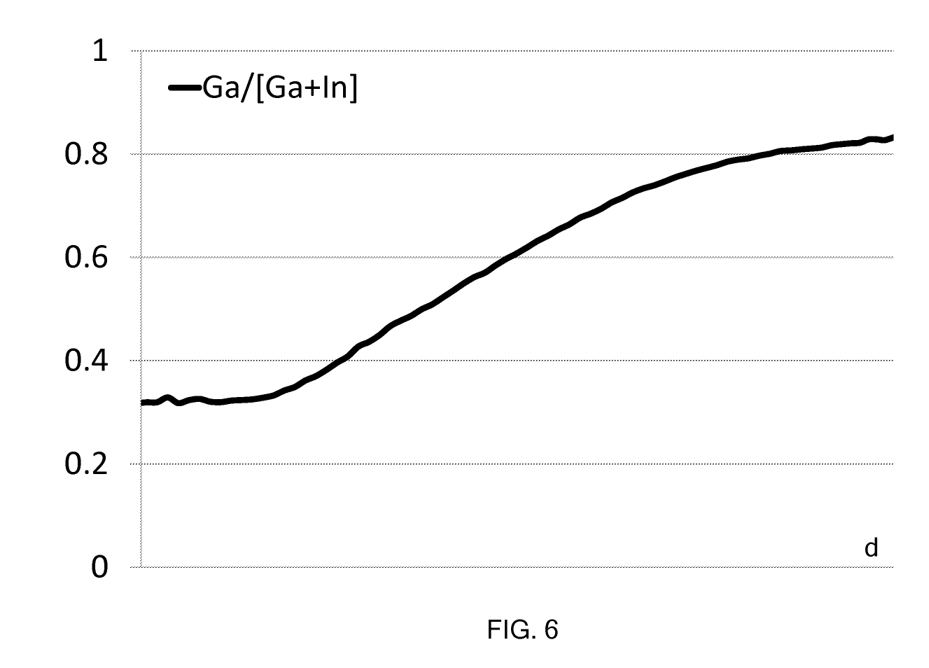

The schematic diagrams in FIGS. 6-8 represent the steps of a process to make a layered substrate which ultimately may be transformed into a single thin film material layer on the substrate. Thus, the schematic diagrams in FIGS. 6-8 do not directly represent the structure of a product material or a substrate article formed from the process.

### Controlling Alkali Ions

Embodiments of this invention can provide methods and compositions for introducing alkali ions at a controlled concentration into various layers and compositions for making a photovoltaic absorber material. Alkali ions can be provided in various layers and the amount of alkali ions can be precisely controlled in making a solar cell.

In some aspects, the ability to control the precise amount and location of alkali ions advantageously allows a solar cell to be made with substrates that do not contain alkali ions. For example, glass, ceramic or metal substrates without sodium, or with low sodium, inorganic substrates, as well as polymer substrates without alkali ions can be used, among others.

This disclosure provides compounds which are soluble in organic solvents and can be used as sources for alkali ions. In some aspects, organic-soluble sources for alkali ions can be used as a component in ink formulations for depositing various layers. Using organic-soluble source compounds for alkali ions allows complete control over the concentration of alkali ions in inks for depositing layers, and for making photovoltaic absorber layers with a precisely controlled concentration of alkali ions.

In some aspects, an ink composition may advantageously be prepared to incorporate alkali metal ions. For example, an ink composition may be prepared using an amount of Na(ER), where E is S or Se and R is alkyl or aryl. R is preferably ⁿBu, ⁱBu, ^{s}Bu, propyl, or hexyl.

In certain embodiments, an ink composition may be prepared using an amount of NaIn(ER)₄, NaGa(ER)₄, LiIn(ER)₄, LiGa(ER)₄, KIn(ER)₄, KGa(ER)₄, or mixtures thereof, where E is S or Se and R is alkyl or aryl. R is preferably ⁿBu, ⁱBu, Bu, propyl, or hexyl. These organic-soluble compounds can be used to control the level of alkali metal ions in an ink or deposited layer.

In certain embodiments, sodium can be provided in an ink at a concentration range of from about 0.01 to 5 atom percent, or from about 0.01 to 2 atom percent, or from about 0.01 to 1 atom percent by dissolving the equivalent amount of NaIn(SeⁿBu)₄, NaGa(SeⁿBu)₄ or NaSeⁿBu.

In further embodiments, sodium can be provided in the process for making a polymeric precursor compound so that the sodium is incorporated into the polymeric precursor compound.

### Annealing Processes for Photovoltaic Absorber Materials

In some aspects, annealing of coated substrates may be performed for forming thin film materials and finished photovoltaic absorber materials.

In certain aspects, an annealing process for coated substrates can be performed in the presence of a chalcogen, for example selenium.

Annealing in the presence of selenium can be performed at a range of times and temperatures. In some embodiments, the temperature of the photovoltaic absorber material is held at about 450° C. for 1 minute. In certain embodiments, the temperature of the photovoltaic absorber material is held at about 525° C. The time for annealing can range from 15 seconds to 60 minutes, or from 30 seconds to five minutes. The temperature for annealing can range from 400° C. to 650° C., or from 450° C. to 550° C.

In additional aspects, the annealing process can include sodium. As discussed above, sodium can be introduced in an ink or a photovoltaic absorber material by using an organic-soluble sodium-containing molecule.

### Methods and Compositions for Stoichiometric Gradients

Embodiments of this invention can provide processes to make thin film materials having a compositional gradient. The compositional gradient may be a variation in the concentration or ratio of any of the atoms in a semiconductor or thin film material.

The process steps shown in FIGS. 6-8 can be used to make a layered substrate having a gradient in the stoichiometry of, for example, a Group 11 or Group 13 atom.

A composition gradient can be formed using a series of polymeric precursor compounds having a sequentially increasing or decreasing concentration or ratio of certain Group 11 or Group 13 atoms.

In some embodiments, the compositional gradient may be represented as a gradient of the ratio of gallium atoms to atoms of indium plus gallium, Ga/(In+Ga). This ratio can be expressed as a percent.

In some embodiments, the compositional gradient may be a gradient of the concentration of indium or gallium, or a gradient of the ratio of atoms of indium to gallium.

In certain embodiments, the compositional gradient may be a gradient of the ratio of atoms of copper to indium or gallium.

In further embodiments, the compositional gradient may be a gradient of the ratio of atoms of copper to silver.

In some embodiments, the compositional gradient may be a gradient of the level of alkali metal ions.

In some variations, the compositional gradient may be a gradient of the ratio of atoms of selenium to sulfur.

A gradient can be a continuous variation in a concentration, or a step-change variation in a concentration.

In some aspects, when the Group 13 atoms present are indium and gallium, the gradient can be measured as the concentration of gallium as a percentage that Ga atoms represent of the total of In plus Ga atoms, Ga/(In+Ga)*100. The gradient can be represented as the change in the percentage Ga/(In+Ga)*100 over distance from the substrate.

In some aspects, when the Group 13 atoms present are indium and aluminum, the gradient can be measured as the concentration of indium as a percentage that In atoms represent of the total of In plus Al atoms, In/(In+Al)*100. The gradient can be represented as the change in the percentage In/(In+Al)*100 over distance from the substrate.

In some aspects, when the Group 13 atoms present are gallium and aluminum, the gradient can be measured as the concentration of gallium as a percentage that Ga atoms represent of the total of Ga plus Al atoms, Ga/(Ga+Al)*100. The gradient can be represented as the change in the percentage Ga/(Ga+Al)*100 over distance from the substrate.

In some embodiments, this invention provides processes for making a CIGS photovoltaic material having a compositional gradient. The compositional gradient can be represented by a change of the ratio of atoms of indium to gallium in a CIGS material according to the formula Cuₓ(In_{1-y}Ga_{y})ᵥ(S_{1-z}Se_{z})_{w}, wherein y can increase from 0.001 to 0.999 as the distance from the substrate increases, and wherein x has a value from 0.5 to 1.5, z is from 0 to 1, v is from 0.5 to 1.5, and w is (3v+x)/2. The value of y represents the fraction that gallium represents of the sum of indium plus gallium. The value of y can also be expressed as a percent, from 0.1% to 99.9%. The gradient will be defined by the change in y over the distance from the substrate.

In some embodiments, this invention provides processes for making a CIGS photovoltaic material having a compositional gradient. The compositional gradient can be represented by a change of the ratio of atoms of copper to atoms of indium plus gallium in a CIGS material according to the formula Cuₓ(In_{1-y}Ga_{y})ᵥ(S_{1-z}Se_{z})_{w}, wherein x/v can increase from ⅓ to 3, which is 0.333 to 3, as the distance from the substrate increases, and wherein y is from 0.001 to 0.999, z is from 0 to 1, v is from 0.5 to 1.5, and w is (3v+x)/2. The value of x/v represents the ratio of copper to the sum of indium plus gallium. The value of x/v can also be expressed as a percent, from 33% to 300%. The gradient will be defined by the change in x/v over the distance from the substrate.

The polymeric precursors may be prepared as a series of ink formulations which represent the compositional gradient.

In some aspects, a layer may be formed with one or more precursors enriched in the quantity of Cu, or deficient in the quantity of Cu.

As used herein, the term transition metals refers to atoms of Groups 3 though 12 of the Periodic Table of the elements recommended by the Commission on the Nomenclature of Inorganic Chemistry and published in IUPAC Nomenclature of Inorganic Chemistry, Recommendations 2005.

### Photovoltaic Absorber Materials

A photovoltaic absorber material may have the empirical formula M^{A}ₓ(M^{B}_{1-y}M^{c}_{y})ᵥ(E¹_{1-z}E²_{z})_{w}, where M^{A} is a Group 11 atom selected from Cu, Ag, and Au, M^{B} and M^{c} are different Group 13 atoms selected from Al, Ga, and In, or a combination thereof, E¹ is S or Se, E² is Se or Te, E¹ and E² are different, x is from 0.5 to 1.5, y is from 0 to 1, and z is from 0 to 1, v is from 0.5 to 1.5, and w is from 1 to 3.

In some embodiments, a photovoltaic absorber material may be a CIS layer on a substrate, wherein the material has the empirical formula CuₓIn_{y}(S_{1-z}Se_{z})_{w}, where x is from 0.5 to 1.5, y is from 0.5 to 1.5, z is from 0 to 1, and w is from 1 to 3.

In some embodiments, a photovoltaic absorber material may be a CIGS layer on a substrate, wherein the material has the empirical formula Cuₓ(In_{1-y}Ga_{y})ᵥ(S_{1-z}Se_{z})_{w}, where x is from 0.5 to 1.5, y is from 0 to 1, and z is from 0 to 1, v is from 0.5 to 1.5, and w is from 1 to 3.

In some embodiments, a photovoltaic absorber material may be a CAIGS layer on a substrate, wherein the material has the empirical formula (Cu₁₋ₓAgₓ)ᵤ(In_{1-y}Ga_{y})ᵥ(S_{1-z}Se_{z})_{w}, where x is from 0.001 to 0.999, y is from 0 to 1, z is from 0 to 1, u is from 0.5 to 1.5, v is from 0.5 to 1.5, and w is from 1 to 3.

Embodiments of this invention may further provide photovoltaic absorber materials that are a CIS, CIGS, AIS, AIGS, CAIS, CAIGS, CIGAS, AIGAS or CAIGAS material.

In some aspects, the thickness of an absorber layer may be from about 0.01 to about 100 micrometers, or from about 0.01 to about 20 micrometers, or from about 0.01 to about 10 micrometers, or from about 0.05 to about 5 micrometers, or from about 0.1 to about 4 micrometers, or from about 0.1 to about 3.5 micrometers, or from about 0.1 to about 3 micrometers, or from about 0.1 to about 2.5 micrometers.

In some embodiments, the thickness of an absorber layer may be from 0.01 to 5 micrometers.

In some embodiments, the thickness of an absorber layer may be from 0.02 to 5 micrometers.

In some embodiments, the thickness of an absorber layer may be from 0.5 to 5 micrometers.

In some embodiments, the thickness of an absorber layer may be from 1 to 3 micrometers.

In some embodiments, the thickness of an absorber layer may be from 100 to 10,000 nanometers.

In some embodiments, the thickness of an absorber layer may be from 10 to 5000 nanometers.

In some embodiments, the thickness of an absorber layer may be from 20 to 5000 nanometers.

In some embodiments, a process for depositing a layer of a precursor on a substrate, an article, or on another layer can have a single step for depositing a thickness of from 20 to 2000 nanometers.

In some embodiments, a process for depositing a layer of a precursor on a substrate, article, or on another layer can have a single step for depositing a thickness of from 100 to 1000 nanometers.

In some embodiments, a process for depositing a layer of a precursor on a substrate, article, or on another layer can have a single step for depositing a thickness of from 200 to 500 nanometers.

In some embodiments, a process for depositing a layer of a precursor on a substrate, article, or on another layer can have a single step for depositing a thickness of from 250 to 350 nanometers.

### Substrates

The precursors of this invention can be used to form a layer on a substrate. The substrate can have any shape. Substrate layers of precursors can be used to create a photovoltaic layer or device.

A substrate may have an electrical contact layer. The electrical contact layer can be on the surface of the substrate. An electrical contact layer on a substrate can be the back contact for a solar cell or photovoltaic device.

Examples of an electrical contact layer include a layer of a metal or a metal foil, as well as a layer of molybdenum, aluminum, copper, gold, platinum, silver, titanium nitride, stainless steel, a metal alloy, and a combination of any of the foregoing.

Examples of substrates on which a polymeric precursor of this disclosure can be deposited or printed include semiconductors, doped semiconductors, silicon, gallium arsenide, insulators, glass, molybdenum glass, silicon dioxide, titanium dioxide, zinc oxide, silicon nitride, and combinations thereof.

A substrate may be coated with molybdenum or a molybdenum-containing compound.

In some embodiments, a substrate may be pre-treated with a molybdenum-containing compound, or one or more compounds containing molybdenum and selenium.

Examples of substrates on which a polymeric precursor of this disclosure can be deposited or printed include metals, metal foils, molybdenum, aluminum, beryllium, cadmium, cerium, chromium, cobalt, copper, gold, manganese, nickel, palladium, platinum, rhenium, rhodium, silver, stainless steel, steel, iron, strontium, tin, titanium, tungsten, zinc, zirconium, metal alloys, metal silicides, metal carbides, and combinations thereof.

Examples of substrates on which a polymeric precursor of this disclosure can be deposited or printed include polymers, plastics, conductive polymers, copolymers, polymer blends, polyethylene terephthalates, polycarbonates, polyesters, polyester films, mylars, polyvinyl fluorides, polyvinylidene fluoride, polyethylenes, polyetherimides, polyethersulfones, polyetherketones, polyimides, polyvinylchlorides, acrylonitrile butadiene styrene polymers, silicones, epoxies, and combinations thereof.

A substrate of this disclosure can be of any shape. Examples of substrates on which a polymeric precursor of this disclosure can be deposited include a shaped substrate including a tube, a cylinder, a roller, a rod, a pin, a shaft, a plane, a plate, a blade, a vane, a curved surface or a spheroid.

A substrate may be layered with an adhesion promoter before the deposition, coating or printing of a layer of a polymeric precursor of this invention.

Examples of adhesion promoters include a glass layer, a metal layer, a titanium-containing layer, a tungsten-containing layer, a tantalum-containing layer, tungsten nitride, tantalum nitride, titanium nitride, titanium nitride silicide, tantalum nitride silicide, a chromium-containing layer, a vanadium-containing layer, a nitride layer, an oxide layer, a carbide layer, and combinations thereof.

Examples of adhesion promoters include organic adhesion promoters such as organofunctional silane coupling agents, silanes, hexamethyldisilazanes, glycol ether acetates, ethylene glycol bis-thioglycolates, acrylates, acrylics, mercaptans, thiols, selenols, tellurols, carboxylic acids, organic phosphoric acids, triazoles, and mixtures thereof.

Substrates may be layered with a barrier layer before the deposition of printing of a layer of a polymeric precursor of this invention.

Examples of a barrier layer include a glass layer, a metal layer, a titanium-containing layer, a tungsten-containing layer, a tantalum-containing layer, tungsten nitride, tantalum nitride, titanium nitride, titanium nitride silicide, tantalum nitride silicide, and combinations thereof.

A substrate can be of any thickness, and can be from about 10 or 20 micrometers to about 20,000 micrometers or more in thickness.

### Ink Compositions

Embodiments of this invention further provide ink compositions which contain one or more precursor compounds or polymeric precursor compounds.

The precursors of this disclosure may be used to make photovoltaic materials by printing an ink onto a substrate.

In some aspects, solution-based processes of this invention for making photovoltaics and solar cells include processes in which a solution is formed by dissolving precursor molecules in a solvent. A precursor molecule can be a polymeric precursor molecule, a monomer precursor molecule, or other soluble precursor molecules.

The solution can be deposited on a substrate in a layer. The deposited of the solution may be dried on the substrate to remove solvent, leaving behind a layer or film of precursor molecules. Addition of energy to the substrate, for example by heating, can be used to convert the film of precursor molecules to a material film. In some embodiments, additional layers of solution may be deposited, dried, and converted to a material film of a desired thickness. In further embodiments, additional layers of solution may be deposited, dried, and converted to a material film of a different composition than other layers or films. The substrate can be annealed, for example by heating, to transform the one or more material films on the substrate into a uniform photovoltaic material. Annealing can be performed in the presence of selenium or selenium vapor. A solar cell can be made with the uniform photovoltaic material on the substrate by finishing steps that are described in various examples herein.

In some aspects, a solution-based process of this invention for making photovoltaics and solar cells can include a pure solution that is formed by dissolving one or more precursor molecules in a solvent. The advantageously enhanced purity of the solution can be due to the complete dissolution of the precursor molecules in the solvent, without residual particles. The precursor molecules can be polymeric precursor molecules or monomer precursor molecules.

Embodiments of this invention provide compositions which contain one or more precursors in a liquid solution. In some embodiments, a composition may contain one or more polymeric precursor compounds dissolved in a solvent.

The solutions of this invention may be used to make photovoltaic materials by depositing the solution onto a substrate. A solution that contains one or more dissolved precursors can be referred to as an ink or ink composition. In certain aspects, an ink can contain one or more dissolved monomer precursors or polymeric precursors.

An ink of this disclosure can advantageously allow precise control of the stoichiometric ratios of certain atoms in the ink because the ink can contain a dissolved polymeric precursor.

An ink of this disclosure advantageously allows precise control of the stoichiometric ratios of certain atoms in the ink because the ink can be composed of one or more polymeric precursor compounds.

Inks of this disclosure can be made by any methods known in the art.

In some embodiments, an ink can be made by mixing a precursor with one or more carriers. The ink may be a suspension of the precursors in an organic carrier. In some variations, the ink is a solution of the precursors in an organic carrier. The carrier can include one or more organic liquids or solvents, and may contain an aqueous component. A carrier may be an organic solvent.

An ink can be made by providing one or more precursor compounds and solubilizing, dissolving, solvating, or dispersing the compounds with one or more carriers. The compounds dispersed in a carrier may be nanocrystalline, nanoparticles, microparticles, amorphous, or dissolved molecules.

The concentration of the precursors in an ink of this disclosure can be from about 0.001% to about 99% (w/w), or from about 0.001% to about 90%, or from about 0.1% to about 90%.

A polymeric precursor may exist in a liquid or flowable phase under the temperature and conditions used for deposition, coating or printing.

As used herein, the term dispersing encompasses the terms solubilizing, dissolving, and solvating.

The carrier for an ink of this disclosure may be an organic liquid or solvent. Examples of a carrier for an ink of this disclosure include one or more organic solvents, which may contain an aqueous component.

Embodiments of this invention further provide precursor compounds having enhanced solubility in one or more carriers for preparing inks. The solubility of a precursor compound can be selected by variation of the nature and molecular size and weight of one or more organic ligands attached to the compound.

An ink composition of this invention may contain any of the dopants disclosed herein, or a dopant known in the art.

Ink compositions of this disclosure can be made by methods known in the art, as well as methods disclosed herein.

Examples of a carrier for an ink of this disclosure include alcohol, methanol, ethanol, isopropyl alcohol, thiols, butanol, butanediol, glycerols, alkoxyalcohols, glycols, 1-methoxy-2-propanol, acetone, ethylene glycol, propylene glycol, propylene glycol laurate, ethylene glycol ethers, diethylene glycol, triethylene glycol monobutylether, propylene glycol monomethylether, 1,2-hexanediol, ethers, diethyl ether, aliphatic hydrocarbons, aromatic hydrocarbons, pentane, hexane, heptane, octane, isooctane, decane, cyclohexane, p-xylene, m-xylene, o-xylene, benzene, toluene, xylene, tetrahydrofuran, 2-methyltetrahydrofuran, siloxanes, cyclosiloxanes, silicone fluids, halogenated hydrocarbons, dibromomethane, dichloromethane, dichloroethane, trichloroethane chloroform, methylene chloride, acetonitrile, esters, acetates, ethyl acetate, butyl acetate, acrylates, isobornyl acrylate, 1,6-hexanediol diacrylate, polyethylene glycol diacrylate, ketones, acetone, methyl ethyl ketone, cyclohexanone, butyl carbitol, cyclopentanone, lactams, N-methylpyrrolidone, N-(2-hydroxyethyl)-pyrrolidone, cyclic acetals, cyclic ketals, aldehydes, amines, diamines, amides, dimethylformamide, methyl lactate, oils, natural oils, terpenes, and mixtures thereof.

An ink of this disclosure may further include components such as a surfactant, a dispersant, an emulsifier, an anti-foaming agent, a dryer, a filler, a resin binder, a thickener, a viscosity modifier, an anti-oxidant, a flow agent, a plasticizer, a conductivity agent, a crystallization promoter, an extender, a film conditioner, an adhesion promoter, and a dye. Each of these components may be used in an ink of this disclosure at a level of from about 0.001% to about 10% or more of the ink composition.

Examples of surfactants include siloxanes, polyalkyleneoxide siloxanes, polyalkyleneoxide polydimethylsiloxanes, polyester polydimethylsiloxanes, ethoxylated nonylphenols, nonylphenoxy polyethyleneoxyethanol, fluorocarbon esters, fluoroaliphatic polymeric esters, fluorinated esters, alkylphenoxy alkyleneoxides, cetyl trimethyl ammonium chloride, carboxymethylamylose, ethoxylated acetylene glycols, betaines, N-n-dodecyl-N,N-dimethylbetaine, dialkyl sulfosuccinate salts, alkylnaphthalenesulfonate salts, fatty acid salts, polyoxyethylene alkylethers, polyoxyethylene alkylallylethers, polyoxyethylene-polyoxypropylene block copolymers, alkylamine salts, quaternary ammonium salts, and mixtures thereof.

Examples of surfactants include anionic, cationic, amphoteric, and nonionic surfactants. Examples of surfactants include SURFYNOL, DYNOL, ZONYL, FLUORAD, and SILWET surfactants.

A surfactant may be used in an ink of this disclosure at a level of from about 0.001% to about 2% of the ink composition.

Examples of a dispersant include a polymer dispersant, a surfactant, hydrophilic-hydrophobic block copolymers, acrylic block copolymers, acrylate block copolymers, graft polymers, and mixtures thereof.

Examples of an emulsifier include a fatty acid derivative, an ethylene stearamide, an oxidized polyethylene wax, mineral oils, a polyoxyethylene alkyl phenol ether, a polyoxyethylene glycol ether block copolymer, a polyoxyethylene sorbitan fatty acid ester, a sorbitan, an alkyl siloxane polyether polymer, polyoxyethylene monostearates, polyoxyethylene monolaurates, polyoxyethylene monooleates, and mixtures thereof.

Examples of an anti-foaming agent include polysiloxanes, dimethylpolysiloxanes, dimethyl siloxanes, silicones, polyethers, octyl alcohol, organic esters, ethyleneoxide propyleneoxide copolymers, and mixtures thereof.

Examples of a dryer include aromatic sulfonic acids, aromatic carboxylic acids, phthalic acid, hydroxyisophthalic acid, N-phthaloylglycine, 2-pyrrolidone 5-carboxylic acid, and mixtures thereof.

Examples of a filler include metallic fillers, silver powder, silver flake, metal coated glass spheres, graphite powder, carbon black, conductive metal oxides, ethylene vinyl acetate polymers, and mixtures thereof.

Examples of a resin binder include acrylic resins, alkyd resins, vinyl resins, polyvinyl pyrrolidone, phenolic resins, ketone resins, aldehyde resins, polyvinyl butyral resin, amide resins, amino resins, acrylonitrile resins, cellulose resins, nitrocellulose resins, rubbers, fatty acids, epoxy resins, ethylene acrylic copolymers, fluoropolymers, gels, glycols, hydrocarbons, maleic resins, urea resins, natural rubbers, natural gums, phenolic resins, cresols, polyamides, polybutadienes, polyesters, polyolefins, polyurethanes, isocynates, polyols, thermoplastics, silicates, silicones, polystyrenes, and mixtures thereof.

Examples of thickeners and viscosity modifiers include conducting polymers, celluloses, urethanes, polyurethanes, styrene maleic anhydride copolymers, polyacrylates, polycarboxylic acids, carboxymethylcelluoses, hydroxyethylcelluloses, methylcelluloses, methyl hydroxyethyl celluloses, methyl hydroxypropyl celluloses, silicas, gellants, aluminates, titanates, gums, clays, waxes, polysaccharides, starches, and mixtures thereof.

Examples of anti-oxidants include phenolics, phosphites, phosphonites, thioesters, stearic acids, ascorbic acids, catechins, cholines, and mixtures thereof.

Examples of flow agents include waxes, celluloses, butyrates, surfactants, polyacrylates, and silicones.

Examples of a plasticizer include alkyl benzyl phthalates, butyl benzyl phthalates, dioctyl phthalates, diethyl phthalates, dimethyl phthalates, di-2-ethylhexy-adipates, diisobutyl phthalates, diisobutyl adipates, dicyclohexyl phthalates, glycerol tribenzoates, sucrose benzoates, polypropylene glycol dibenzoates, neopentyl glycol dibenzoates, dimethyl isophthalates, dibutyl phthalates, dibutyl sebacates, tri-n-hexyltrimellitates, and mixtures thereof.

Examples of a conductivity agent include lithium salts, lithium trifluoromethanesulfonates, lithium nitrates, dimethylamine hydrochlorides, diethylamine hydrochlorides, hydroxylamine hydrochlorides, and mixtures thereof.

Examples of a crystallization promoter include copper chalcogenides, alkali metal chalcogenides, alkali metal salts, alkaline earth metal salts, sodium chalcogenates, cadmium salts, cadmium sulfates, cadmium sulfides, cadmium selenides, cadmium tellurides, indium sulfides, indium selenides, indium tellurides, gallium sulfides, gallium selenides, gallium tellurides, molybdenum, molybdenum sulfides, molybdenum selenides, molybdenum tellurides, molybdenum-containing compounds, and mixtures thereof.

An ink may contain one or more components selected from the group of a conducting polymer, silver metal, silver selenide, silver sulfide, copper metal, indium metal, gallium metal, zinc metal, alkali metals, alkali metal salts, alkaline earth metal salts, sodium chalcogenates, calcium chalcogenates, cadmium sulfide, cadmium selenide, cadmium telluride, indium sulfide, indium selenide, indium telluride, gallium sulfide, gallium selenide, gallium telluride, zinc sulfide, zinc selenide, zinc telluride, copper sulfide, copper selenide, copper telluride, molybdenum sulfide, molybdenum selenide, molybdenum telluride, and mixtures of any of the foregoing.

An ink of this disclosure may contain particles of a metal, a conductive metal, or an oxide. Examples of metal and oxide particles include silica, alumina, titania, copper, iron, steel, aluminum and mixtures thereof.

In certain variations, an ink may contain a biocide, a sequestering agent, a chelator, a humectant, a coalescent, or a viscosity modifier.

In certain aspects, an ink of this disclosure may be formed as a solution, a suspension, a slurry, or a semisolid gel or paste. An ink may include one or more precursors solubilized in a carrier, or may be a solution of the precursors. In certain variations, a precursor may include particles or nanoparticles that can be suspended in a carrier, and may be a suspension or paint of the precursors. In certain embodiments, a precursor can be mixed with a minimal amount of a carrier, and may be a slurry or semisolid gel or paste of the precursor.

The viscosity of an ink of this disclosure can be from about 0.5 centipoises (cP) to about 50 cP, or from about 0.6 to about 30 cP, or from about 1 to about 15 cP, or from about 2 to about 12 cP.

The viscosity of an ink of this disclosure can be from about 20 cP to about 2×10⁶ cP, or greater. The viscosity of an ink of this disclosure can be from about 20 cP to about 1×10⁶ cP, or from about 200 cP to about 200,000 cP, or from about 200 cP to about 100,000 cP, or from about 200 cP to about 40,000 cP, or from about 200 cP to about 20,000 cP.

The viscosity of an ink of this disclosure can be about 1 cP, or about 2 cP, or about 5 cP, or about 20 cP, or about 100 cP, or about 500 cP, or about 1,000 cP, or about 5,000 cP, or about 10,000 cP, or about 20,000 cP, or about 30,000 cP, or about 40,000 cP.

In some embodiments, an ink may contain one or more components from the group of a surfactant, a dispersant, an emulsifier, an anti-foaming agent, a dryer, a filler, a resin binder, a thickener, a viscosity modifier, an anti-oxidant, a flow agent, a plasticizer, a conductivity agent, a crystallization promoter, an extender, a film conditioner, an adhesion promoter, and a dye. In certain variations, an ink may contain one or more compounds from the group of cadmium sulfide, cadmium selenide, cadmium telluride, zinc sulfide, zinc selenide, zinc telluride, copper sulfide, copper selenide, and copper telluride. In some aspects, an ink may contain particles of a metal, a conductive metal, or an oxide.

An ink may be made by dissolving one or more compounds of this disclosure in one or more carriers to form a dispersion or solution.

An ink may be made by dispersing one or more precursor compounds of this disclosure in one or more carriers to form a dispersion or solution.

In some embodiments, an ink can be made with one or more precursor compounds having the empirical formula M^{B}(ER)₃, where M^{B} is Al, Ga, or In, and R is selected from alkyl, aryl, heteroaryl, alkenyl, amido, silyl, and inorganic and organic groups.

In certain embodiments, an ink can be made with one or more precursor compounds having the empirical formula M^{A}(ER), where M^{A} is Cu, Ag, or Au, and R is selected from alkyl, aryl, heteroaryl, alkenyl, amido, silyl, and inorganic and organic groups.

An ink composition can be prepared by dispersing one or more precursors in a solvent, and heating the solvent to dissolve or disperse the precursors. The precursors may have a concentration of from about 0.001% to about 99% (w/w), or from about 0.001% to about 90%, or from about 0.1% to about 90%, or from about 0.1% to about 50%, or from about 0.1% to about 40%, or from about 0.1% to about 30%, or from about 0.1% to about 20%, or from about 0.1% to about 10% in the solution or dispersion.

An ink composition may further contain an additional indium-containing compound, or an additional gallium-containing compound. Examples of additional indium-containing compounds include In(SeR)₃, wherein R is alkyl or aryl. Examples of additional gallium-containing compounds include Ga(SeR)₃, wherein R is alkyl or aryl. For example, an ink may further contain In(SeⁿBu)₃ or Ga(SeⁿBu)₃, or mixtures thereof. In some embodiments, an ink may contain Na(ER), where E is S or Se and R is alkyl or aryl. In certain embodiments, an ink may contain NaIn(ER)₄, NaGa(ER)₄, LiIn(ER)₄, LiGa(ER)₄, KIn(ER)₄, or KGa(ER)₄, where E is S or Se and R is alkyl or aryl. In certain embodiments, an ink may contain Cu(ER). For these additional compounds, R is preferably ⁿBu, ⁱBu, ^{s}Bu, or Pr.

In some examples, an ink composition may contain In(SeR)₃.

In further examples, an ink composition may contain Ga(SeR)₃.

For example, an ink composition may contain In(SeR)₃ and Ga(SeR)₃, wherein the ratio of In to Ga in the ink is 10:90, or 20:80, or 30:70, or 40:60, or 50:50, or 60:40, or 70:30, or 80:20, or 90:10, or any integer value between those values.

In another example, an ink composition may contain In(SR)₃ and Ga(SR)₃, wherein the ratio of In to Ga in the ink is 10:90, or 20:80, or 30:70, or 40:60, or 50:50, or 60:40, or 70:30, or 80:20, or 90:10, or any integer value between those values.

In another example, an ink composition may contain any of the compounds In(SeR)₃, Ga(SeR)₃, In(SR)₃ and Ga(SR)₃, wherein the overall ratio of In to Ga in the ink is 10:90, or 20:80, or 30:70, or 40:60, or 50:50, or 60:40, or 70:30, or 80:20, or 90:10, or any integer value between those values.

In another example, an ink composition may contain any of the monomer compounds of this disclosure, wherein the overall ratio of In to Ga in the ink is 10:90, or 20:80, or 30:70, or 40:60, or 50:50, or 60:40, or 70:30, or 80:20, or 90:10, or any integer value between those values.

### Processes for Films of Precursors on Substrates

As used herein, the terms “deposit,” “depositing,” and “deposition” refer to any method for placing a compound or composition onto a surface or substrate, including spraying, coating, and printing.

As used herein, the term “thin film” refers to a layer of atoms or molecules, or a composition layer on a substrate having a thickness of less than about 300 micrometers.

Examples of methods for depositing a precursor onto a surface or substrate include all forms of spraying, coating, and printing.

The depositing of compounds by spraying can be done at rates from about 10 nm to 3 micrometers per minute, or from 100 nm to 2 micrometers per minute.

Examples of methods for depositing a precursor onto a surface or substrate include spraying, spray coating, spray deposition, spray pyrolysis, and combinations thereof.

Examples of methods for printing using an ink of this disclosure include printing, screen printing, inkjet printing, aerosol jet printing, ink printing, jet printing, stamp/pad printing, transfer printing, pad printing, flexographic printing, gravure printing, contact printing, reverse printing, thermal printing, lithography, electrophotographic printing, and combinations thereof.

Examples of methods for depositing a precursor onto a surface or substrate include electrodepositing, electroplating, electroless plating, bath deposition, coating, dip coating, wet coating, spin coating, knife coating, roller coating, rod coating, slot die coating, meyerbar coating, lip direct coating, capillary coating, liquid deposition, solution deposition, layer-by-layer deposition, spin casting, and solution casting.

For various methods of depositing precursors, thickness per pass can be from 75 to 150 nm, or from 10 to 3000 nm, or from 10 to 2000 nm, or from 100 to 1000 nm, or from 200 to 500 nm, or from 250 to 350 nm.

For various methods of depositing precursors, thickness per pass can be up to 1000 nm or greater.

For depositing precursors by spraying, spray coating, spray deposition, spray pyrolysis, printing, screen printing, inkjet printing, aerosol jet printing, ink printing, jet printing, stamp printing, transfer printing, pad printing, flexographic printing, gravure printing, contact printing, reverse printing, thermal printing, lithography, electrophotographic printing, electrodepositing, electroplating, electroless plating, bath deposition, coating, wet coating, dip coating spin coating, knife coating, roller coating, rod coating, slot die coating, meyerbar coating, lip direct coating, capillary coating, liquid deposition, solution deposition, layer-by-layer deposition, spin casting, or solution casting, thickness per pass can be from 10 to 3000 nm, or from 10 to 2000 nm, or from 100 to 1000 nm, or from 200 to 500 nm, or from 250 to 350 nm.

For depositing precursors by coating, wet coating, dip coating spin coating, knife coating, roller coating, rod coating, slot die coating, meyerbar coating, lip direct coating, capillary coating, liquid deposition, solution deposition, layer-by-layer deposition, spin casting, or solution casting, thickness per pass can be from 10 to 3000 nm, or from 10 to 2000 nm, or from 100 to 1000 nm, or from 200 to 500 nm, or from 250 to 350 nm.

For depositing precursors by coating, knife coating, rod coating, or slot die coating, thickness per pass can be from 10 to 3000 nm, or from 10 to 2000 nm, or from 100 to 1000 nm, or from 200 to 500 nm, or from 250 to 350 nm.

For depositing precursors by coating or knife coating, thickness per pass can be from 10 to 3000 nm, or from 10 to 2000 nm, or from 100 to 1000 nm, or from 200 to 500 nm, or from 250 to 350 nm.

In certain embodiments, crack-free films are achieved with a process having a step with a thickness per pass of 50 nm, 75 nm, 100 nm, 200 nm, 300 nm, 350 nm, 400 nm, 500 nm, 600 nm or greater.

The coated substrate can be annealed after depositing any number of layers of precursors.

Examples of methods for depositing a precursor onto a surface or substrate include chemical vapor deposition, aerosol chemical vapor deposition, metal-organic chemical vapor deposition, organometallic chemical vapor deposition, plasma enhanced chemical vapor deposition, and combinations thereof.

In certain embodiments, a first polymeric precursor may be deposited onto a substrate, and subsequently a second polymeric precursor may be deposited onto the substrate. In certain embodiments, several different polymeric precursors may be deposited onto the substrate to create a layer.

In certain variations, different precursors may be deposited onto a substrate simultaneously, or sequentially, whether by spraying, coating, printing, or by other methods. The different precursors may be contacted or mixed before the depositing step, during the depositing step, or after the depositing step. The precursors can be contacted before, during, or after the step of transporting the precursors to the substrate surface.

The depositing of precursors, including by spraying, coating, and printing, can be done in a controlled or inert atmosphere, such as in dry nitrogen and other inert gas atmospheres, as well as in a partial vacuum atmosphere.

Processes for depositing, spraying, coating, or printing precursors can be done at various temperatures including from about −20° C. to about 650° C., or from about −20° C. to about 600° C., or from about −20° C. to about 400° C., or from about 20° C. to about 360° C., or from about 20° C. to about 300° C., or from about 20° C. to about 250° C.

Processes for making a solar cell involving a step of transforming a precursor compound into a material or semiconductor can be performed at various temperatures including from about 100° C. to about 650° C., or from about 150° C. to about 650° C., or from about 250° C. to about 650° C., or from about 300° C. to about 650° C., or from about 400° C. to about 650° C., or from about 300° C. to about 600° C., or from about 300° C. to about 550° C., or from about 300° C. to about 500° C., or from about 300° C. to about 450° C.

In certain aspects, depositing of precursors on a substrate can be done while the substrate is heated. In these variations, a thin-film material may be deposited or formed on the substrate.

In some embodiments, a step of converting a precursor to a material and a step of annealing can be done simultaneously. In general, a step of heating a precursor can be done before, during or after any step of depositing the precursor.

In some variations, a substrate can be cooled after a step of heating. In certain embodiments, a substrate can be cooled before, during, or after a step of depositing a precursor. A substrate may be cooled to return the substrate to a lower temperature, or to room temperature, or to an operating temperature of a deposition unit. Various coolants or cooling methods can be applied to cool a substrate.

The depositing of precursors on a substrate may be done with various apparatuses and devices known in art, as well as devices described herein.

In some variations, the depositing of precursors can be performed using a spray nozzle with adjustable nozzle dimensions to provide a uniform spray composition and distribution.

Embodiments of this disclosure further contemplate articles made by depositing a layer onto a substrate, where the layer contains one or more precursors.

The article may be a substrate having a layer of a film, or a thin film, which is deposited, sprayed, coated, or printed onto the substrate. In certain variations, an article may have a substrate printed with a precursor ink, where the ink is printed in a pattern on the substrate.

After conversion of the coated substrate, another precursor coating may be applied to the thin film material on the substrate by repeating the procedure above. This process can be repeated to prepare additional thin film material layers on the substrate.

After the last thin film material layer is prepared on the substrate, the substrate can be annealed. The annealing process may include a step of heating the coated substrate at a temperature sufficient to convert the coating on the substrate to a thin film photovoltaic material. The annealing process may include a step of heating the coated substrate at 400° C. for 60 min, or 500° C. for 30 min, or 550° C. for 60 min, or 550° C. for 20 min. The annealing process may include an additional step of heating the coated substrate at 550° C. for 10 min, or 525° C. for 10 min, or 400° C. for 5 min.

### Photovoltaic Devices

In further examples, a thin film material photovoltaic absorber layer can be made by providing a precursor ink which is filtered with a 0.45 micron filter, or a 0.3 micron filter. The ink may be printed onto a polyethylene terephthalate substrate using a inkjet printer in a glovebox in an inert atmosphere. A film of about 0.1 to 5 microns thickness can be deposited on the substrate. The substrate can be removed and heated at a temperature of from about 100° C. to about 600° C., or from about 100° C. to about 650° C. in an inert atmosphere, thereby producing a thin film material photovoltaic absorber layer.

Methods for making a photovoltaic absorber layer on a substrate include providing one or more precursor compounds, providing a substrate, spraying the compounds onto the substrate, and heating the substrate at a temperature of from about 100° C. to about 600° C., or of from about 100° C. to about 650° C. in an inert atmosphere, thereby producing a photovoltaic absorber layer having a thickness of from 0.01 to 100 micrometers. The spraying can be done in spray coating, spray deposition, jet deposition, or spray pyrolysis. The substrate may be glass, metal, polymer, plastic, or silicon.

The photovoltaic absorber layer made by the methods of this disclosure may have an empirical formula Cuₓ(In_{1-y}Ga_{y})ᵥ(S_{1-z}Se_{z})_{w}, where x is from 0.8 to 0.95, y is from 0 to 0.5, and z is from 0 to 1, v is from 0.95 to 1.05, and w is from 1.8 to 2.2. In some embodiments, w is from 2.0 to 2.2. The photovoltaic absorber layer made by the methods of this disclosure may have an empirical formula empirical formula CuₓIn_{y}(S_{1-z}Se_{z})_{w}, where x is from 0.8 to 0.95, y is from 0.95 to 1.05, z is from 0 to 1, and w is from 1.8 to 2.2. Methods for making a photovoltaic absorber layer can include a step of sulfurization or selenization.

In certain variations, methods for making a photovoltaic absorber layer may include heating the compounds to a temperature of from about 20° C. to about 400° C. while depositing, spraying, coating, or printing the compounds onto the substrate.

Methods for making a photovoltaic absorber layer on a substrate include providing one or more precursor compounds, providing a substrate, depositing the compounds onto the substrate, and heating the substrate at a temperature of from about 100° C. to about 650° C., or from about 100° C. to about 600° C., or from about 100° C. to about 400° C., or from about 100° C. to about 300° C. in an inert atmosphere, thereby producing a photovoltaic absorber layer having a thickness of from 0.01 to 100 micrometers. The depositing can be done in electrodepositing, electroplating, electroless plating, bath deposition, liquid deposition, solution deposition, layer-by-layer deposition, spin casting, or solution casting. The substrate may be glass, metal, polymer, plastic, or silicon.

Methods for making a photovoltaic absorber layer on a substrate include providing one or more precursor inks, providing a substrate, printing the inks onto the substrate, and heating the substrate at a temperature of from about 100° C. to about 600° C., or from about 100° C. to about 650° C. in an inert atmosphere, thereby producing a photovoltaic absorber layer having a thickness of from 0.01 to 100 micrometers. The printing can be done in screen printing, inkjet printing, transfer printing, flexographic printing, or gravure printing. The substrate may be glass, metal, polymer, plastic, or silicon. The method may further include adding to the ink an additional indium-containing compound, such as In(SeR)₃, wherein R is alkyl or aryl.

In general, an ink composition for depositing, spraying, or printing may contain an additional indium-containing compound, or an additional gallium-containing compound. Examples of additional indium-containing compounds include In(SeR)₃, wherein R is alkyl or aryl. Examples of additional gallium-containing compounds include Ga(SeR)₃, wherein R is alkyl or aryl. For example, an ink may further contain In(SeⁿBu)₃ or Ga(SeⁿBu)₃, or mixtures thereof. In some embodiments, an ink may contain Na(ER), where E is S or Se and R is alkyl or aryl. In certain embodiments, an ink may contain NaIn(ER)₄, NaGa(ER)₄, LiIn(ER)₄, LiGa(ER)₄, KIn(ER)₄, or KGa(ER)₄, where E is S or Se and R is alkyl or aryl.

### DEFINITIONS

As used herein, the term atom percent, atom %, or at % refers to the amount of an atom with respect to the final material in which the atoms are incorporated. For example, “0.5 at % Na in CIGS” refers to an amount of sodium atoms equivalent to 0.5 atom percent of the atoms in the CIGS material.

As used herein, the term (X,Y) when referring to compounds or atoms indicates that either X or Y, or a combination thereof may be found in the formula. For example, (S,Se) indicates that atoms of either sulfur or selenium, or any combination thereof may be found. Further, using this notation the amount of each atom can be specified. For example, when appearing in the chemical formula of a molecule, the notation (0.75 In, 0.25 Ga) indicates that the atom specified by the symbols in the parentheses is indium in 75% of the compounds and gallium in the remaining 25% of the compounds, regardless of the identity any other atoms in the compound. In the absence of a specified amount, the term (X,Y) refers to approximately equal amounts of X and Y.

The atoms S, Se, and Te of Group 16 are referred to as chalcogens.

As used herein, the letter “S” in CIGS, AIGS, CAIGS, CIGAS, AIGAS and CAIGAS refers to sulfur or selenium or both. The letter “C” in CIGS, CAIGS, CIGAS, and CAIGAS refers to copper. The letter “A” in AIGS, CAIGS, AIGAS and CAIGAS which appears before the letters I and G refers to silver. The letter “I” in CIGS, AIGS, CAIGS, CIGAS, AIGAS and CAIGAS refers to indium. The letter “G” in CIGS, AIGS, CAIGS, CIGAS, AIGAS and CAIGAS refers to gallium. The letter “A” in CIGAS, AIGAS and CAIGAS which appears after the letters I and G refers to aluminum.

CAIGAS therefore could also be represented as Cu/Ag/In/Ga/Al/S/Se.

As used herein, the terms CIGS, AIGS, and CAIGS include the variations C(I,G)S, A(I,G)S, and CA(I,G)S, respectively, and CIS, AIS, and CAIS, respectively, as well as CGS, AGS, and CAGS, respectively, unless described otherwise.

The terms CIGAS, AIGAS and CAIGAS include the variations C(I,G,A)S, A(I,G,A)S, and CA(I,G,A)S, respectively, and CIGS, AIGS, and CAIGS, respectively, as well as CGAS, AGAS, and CAGAS, respectively, unless described otherwise.

The term CAIGAS refers to variations in which either C or Silver is zero, for example, AIGAS and CIGAS, respectively, as well as variations in which Aluminum is zero, for example, CAIGS, AIGS, and CIGS.

As used herein, the term CIGS includes the terms CIGSSe and CIGSe, and these terms refer to compounds or materials containing copper/indium/gallium/sulfur/selenium, which may contain sulfur or selenium or both. The term AIGS includes the terms AIGSSe and AIGSe, and these terms refer to compounds or materials containing silver/indium/gallium/sulfur/selenium, which may contain sulfur or selenium or both. The term CAIGS includes the terms CAIGSSe and CAIGSe, and these terms refer to compounds or materials containing copper/silver/indium/gallium/sulfur/selenium, which may contain sulfur or selenium or both.

As used herein, the term “chalcogenide” refers to a compound containing one or more chalcogen atoms bonded to one or more metal atoms.

The term “alkyl” as used herein refers to a hydrocarbyl radical of a saturated aliphatic group, which can be a branched or unbranched, substituted or unsubstituted aliphatic group containing from 1 to 22 carbon atoms. This definition applies to the alkyl portion of other groups such as, for example, cycloalkyl, alkoxy, alkanoyl, aralkyl, and other groups defined below. The term “cycloalkyl” as used herein refers to a saturated, substituted or unsubstituted cyclic alkyl ring containing from 3 to 12 carbon atoms. As used herein, the term “C(1-5)alkyl” includes C(1)alkyl, C(2)alkyl, C(3)alkyl, C(4)alkyl, and C(5)alkyl.

As used herein, an alkyl group may be designated by a term such as Me (methyl), Et (ethyl), Pr (any propyl group), ⁿPr (n-Pr, n-propyl), ⁱPr (i-Pr, isopropyl), Bu (any butyl group), ⁿBu (n-Bu, n-butyl), ⁱBu (i-Bu, isobutyl), ^{s}Bu (s-Bu, sec-butyl), and ^{t}Bu (t-Bu, tert-butyl).

The priority patent documents U.S. Ser. No. 13/233,998, filed Sep. 15, 2011, US61/498,383, filed Jun. 17, 2011, US61/439,735, filed Feb. 4, 2011, US61/383,292, filed Sep. 15, 2010, U.S. Ser. No. 13/417,684, filed Mar. 12, 2012, US61/498,383, filed Jun. 17, 2011, and all publications, references, patents, patent publications and patent applications cited herein are each hereby specifically incorporated by reference in their entirety for all purposes.

While this invention has been described in relation to certain embodiments, aspects, or variations, and many details have been set forth for purposes of illustration, it will be apparent to those skilled in the art that this invention includes additional embodiments, aspects, or variations, and that some of the details described herein may be varied considerably without departing from this invention. This invention includes such additional embodiments, aspects, and variations, and any modifications and equivalents thereof. In particular, this invention includes any combination of the features, terms, or elements of the various illustrative components and examples.

The use herein of the terms “a,” “an,” “the” and similar terms in describing the invention, and in the claims, are to be construed to include both the singular and the plural.

The terms “comprising,” “having,” “include,” “including” and “containing” are to be construed as open-ended terms which mean, for example, “including, but not limited to.” Thus, terms such as “comprising,” “having,” “include,” “including” and “containing” are to be construed as being inclusive, not exclusive.

The examples given herein, and the exemplary language used herein are solely for the purpose of illustration, and are not intended to limit the scope of the invention. All examples and lists of examples are understood to be non-limiting.

When a list of examples is given, such as a list of compounds, molecules or compositions suitable for this invention, it will be apparent to those skilled in the art that mixtures of the listed compounds, molecules or compositions may also be suitable.

### EXAMPLES

### Example 1

A material having the composition of CIGS was made by the following process.

A first ink was prepared containing a CIGS polymeric precursor compound having the empirical formula {Cu_{0.85}In_{0.1}Ga_{0.9}(Se^{t}Bu)_{0.85}(SeⁿBu)_{3.0}} and 0.5 at % Na from NaIn(SeⁿBu)₄ by dissolving in octane under inert atmosphere to a concentration of 25% polymeric precursor content by weight. The resulting ink was filtered through a 0.2 μm PTFE syringe filter prior to use.

A second ink was prepared containing a CIGS polymeric precursor compound having the empirical formula {Cu_{0.85}In_{0.9}Ga_{0.1}(Se^{t}Bu)_{0.85}(SeⁿBu)_{3.0}} and 0.5 at % Na from NaIn(SeⁿBu)₄ by dissolving in octane to a concentration of 25% polymeric precursor content by weight. The resulting ink was filtered through a 0.2 μm PTFE syringe filter prior to use.

The substrate was a Mo-coated sodalime glass with a 100 nm layer of the material Cu_{1.1}In_{0.1}Ga_{0.9}Se_{2.1} on the surface on which the inks were deposited.

Ink volumes were 0.04 mL and knife coating speeds were 20 mm/sec.

An aliquot of the first ink was deposited in a single layer onto the substrate using a knife coater in an inert atmosphere glove box. The wet substrate was heated on a pre-heated 320° C. hot plate for 3 minutes.

A second aliquot of the first ink was deposited onto the substrate using a knife coater in an inert atmosphere glove box. The wet substrate was again heated on a pre-heated 320° C. hot plate for 3 minutes.

An additional four layers of the first ink were coated and heated in a like manner for a total of six layers, resulting in a film on the substrate.

An aliquot of the second ink was deposited by knife coating onto the film on the substrate. The wet substrate was heated on a pre-heated 320° C. hot plate for 3 minutes. Following this, five additional layers of the second ink were deposited and heated in a like manner.

The substrate was then heated on a pre-heated hot plate at 320° C. for 10 minutes.

The resulting thin film CIGS material on the substrate had a thickness of 1.2 μm.

SIMS analysis showed that the concentration of Ga at the substrate side of the film (back side, or Mo-side) was Ga/(In+Ga)=0.88, and the concentration of Ga at the surface of the film away from the substrate (front side of the film) was Ga/(In+Ga)=0.12.

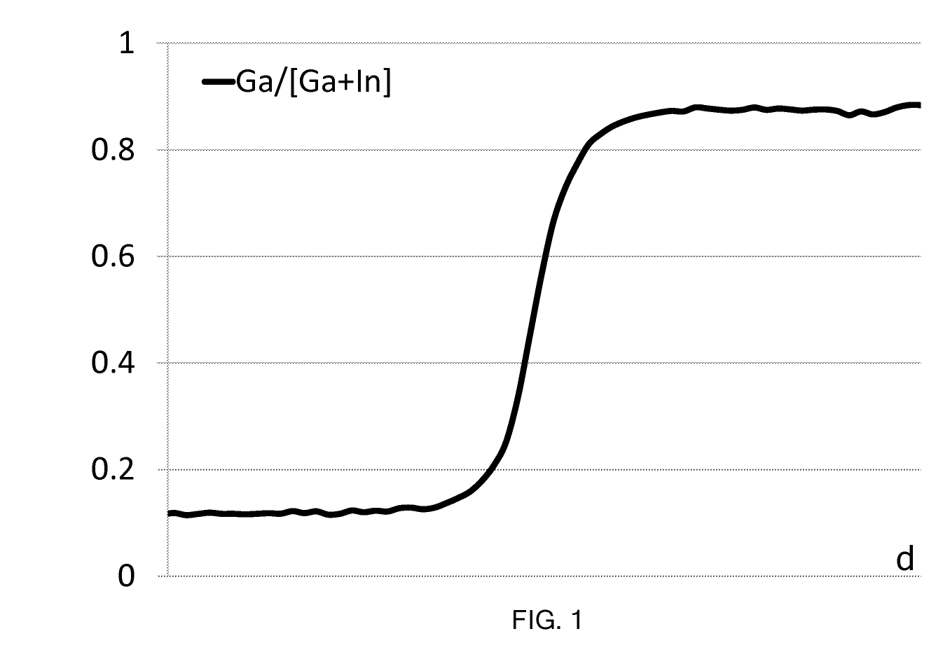

FIG. 1 shows a chart of the compositional gradient of gallium in the thin film CIGS material as measured by SIMS. The chart of FIG. 1 shows a step-down gradient of gallium concentration as the distance from the substrate increases.

### Example 2

A CIGS photovoltaic absorber material was made by the following process.

A first ink was prepared containing a CIGS polymeric precursor compound having the empirical formula {Cu_{0.85}In_{0.1}Ga_{0.9}(Se^{t}Bu)_{0.85}(SeⁿBu)_{3.0}} and 0.5 at % Na from NaIn(SeⁿBu)₄ by dissolving in octane under inert atmosphere to a concentration of 25% polymeric precursor content by weight. The resulting ink was filtered through a 0.2 μm PTFE syringe filter prior to use.

A second ink was prepared containing a CIGS polymeric precursor compound having the empirical formula {Cu_{0.85}In_{0.9}Ga_{0.1}(Se^{t}Bu)_{0.85}(SeⁿBu)_{3.0}} and 0.5 at % Na from NaIn(SeⁿBu)₄ by dissolving in octane to a concentration of 25% polymeric precursor content by weight. The resulting ink was filtered through a 0.2 μm PTFE syringe filter prior to use.

The substrate was a Mo-coated sodalime glass with a 100 nm layer of the material Cu_{1.1}In_{0.1}Ga_{0.9}Se_{2.1} on the surface on which the inks were deposited.

Ink volumes were 0.04 mL and knife coating speeds were 20 mm/sec. An aliquot of the first ink was deposited in a single layer onto the substrate using a knife coater in an inert atmosphere glove box. The wet substrate was heated on a pre-heated 320° C. hot plate for 3 minutes.

A second aliquot of the first ink was deposited onto the substrate using a knife coater in an inert atmosphere glove box. The wet substrate was again heated on a pre-heated 320° C. hot plate for 3 minutes.

An additional four layers of the first ink were coated and heated in a like manner for a total of six layers, resulting in a film on the substrate.

An aliquot of the second ink was deposited by knife coating onto the film on the substrate. The wet substrate was heated on a pre-heated 320° C. hot plate for 3 minutes. Following this, five additional layers of the second ink were deposited and heated in a like manner.

The substrate was then heated on a pre-heated hot plate at 530° C. for 10 minutes.

The resulting thin film CIGS material on the substrate had a thickness of 1.2 μm.

SIMS analysis showed that the concentration of Ga at the substrate side of the film (back side, or Mo-side) was Ga/(In+Ga)=0.81, and the concentration of Ga at the surface of the film away from the substrate (front side of the film) was Ga/(In+Ga)=0.22.

FIG. 2 shows a chart of a compositional gradient of gallium in the thin film CIGS material as measured by SIMS. The chart of FIG. 2 shows a continuous downhill gradient of gallium concentration as the distance from the substrate increases.

A film made by a similar process wherein the substrate was heated at 490° C. for 23 minutes in the presence of selenium vapor in the last step had no gradient in gallium.

### Example 3

A CIGS photovoltaic absorber material was made by the following process.

A first ink was prepared containing a CIGS polymeric precursor compound having the empirical formula {Cu_{0.85}In_{0.1}Ga_{0.9}(Se^{t}Bu)_{0.85}(SeⁿBu)_{3.0}} and 1.0 at % Na from NaIn(SeⁿBu)₄ by dissolving in octane under inert atmosphere to a concentration of 25% polymeric precursor content by weight. The resulting ink was filtered through a 0.2 μm PTFE syringe filter prior to use.

A second ink was prepared containing a CIGS polymeric precursor compound having the empirical formula {Cu_{0.85}In_{0.9}Ga_{0.1}(Se^{t}Bu)_{0.85}(SeⁿBu)_{3.0}} and 1.0 at % Na from NaIn(SeⁿBu)₄ by dissolving in octane to a concentration of 25% polymeric precursor content by weight. The resulting ink was filtered through a 0.2 μm PTFE syringe filter prior to use.

The substrate was a Mo-coated sodalime glass with a 100 nm layer of the material Cu_{1.1}In_{0.1}Ga_{0.9}Se_{2.1} on the surface on which the inks were deposited.

Ink volumes were 0.04 mL and knife coating speeds were 20 mm/sec.

An aliquot of the first ink was deposited in a single layer onto the substrate using a knife coater in an inert atmosphere glove box. The wet substrate was heated on a pre-heated 320° C. hot plate for 3 minutes.

A second aliquot of the first ink was deposited onto the substrate using a knife coater in an inert atmosphere glove box. The wet substrate was again heated on a pre-heated 320° C. hot plate for 3 minutes.

An additional six layers of the first ink were coated and heated in a like manner for a total of eight layers, resulting in a film on the substrate.

The substrate was then heated in a pre-heated furnace at 490° C. for 10 minutes, followed by heating at 490° C. for 8 minutes while being exposed to Se vapor.

An aliquot of the second ink was deposited by knife coating onto the film on the substrate. The wet substrate was heated on a pre-heated 320° C. hot plate for 3 minutes. Following this, seven additional layers of the second ink were deposited and heated in a like manner.

The substrate was then heated in a pre-heated furnace at 490° C. for 10 minutes, followed by heating at 490° C. for 3 minutes while being exposed to Se vapor.

The resulting thin film CIGS material on the substrate had a thickness of 1.5 μm.

SIMS analysis showed that the concentration of Ga at the substrate side of the film (back side, or Mo-side) was Ga/(In+Ga)=0.65, and the concentration of Ga at the surface of the film away from the substrate (front side of the film) was Ga/(In+Ga)=0.35.

FIG. 3 shows a chart of a compositional gradient of gallium in the thin film CIGS material as measured by SIMS. The chart of FIG. 3 shows a continuous downhill gradient of gallium concentration as the distance from the substrate increases.

### Example 4

A CIGS photovoltaic absorber material was made by the following process.

A first ink was prepared containing a CIGS polymeric precursor compound having the empirical formula {Cu_{0.85}In_{0.1}Ga_{0.9}(SeBu)_{0.85}(SeⁿBu)_{3.0}} and 1.0 at % Na from NaIn(SeⁿBu)₄ by dissolving in octane under inert atmosphere to a concentration of 25% polymeric precursor content by weight. The resulting ink was filtered through a 0.2 μm PTFE syringe filter prior to use.

A second ink was prepared containing a CIGS polymeric precursor compound having the empirical formula {Cu_{0.85}In_{0.9}Ga_{0.1}(Se^{t}Bu)_{0.85}(SeⁿBu)_{3.0}} without Na by dissolving in octane to a concentration of 25% polymeric precursor content by weight. The resulting ink was filtered through a 0.2 μm PTFE syringe filter prior to use.

A third ink was prepared containing a CIGS polymeric precursor compound having the empirical formula {Cu_{0.85}In_{0.9}Ga_{0.1}(SeBu)_{0.85}(SeⁿBu)_{3.0}} and 1.0 at % Na from NaIn(SeⁿBu)₄ by dissolving in octane to a concentration of 25% polymeric precursor content by weight. The resulting ink was filtered through a 0.2 μm PTFE syringe filter prior to use.

The substrate was a Mo-coated sodalime glass with a 100 nm layer of the material Cu_{1.1}In_{0.1}Ga_{0.9}Se_{2.1} on the surface on which the inks were deposited.

Ink volumes were 0.04 mL and knife coating speeds were 20 mm/sec.

An aliquot of the first ink was deposited in a single layer onto the substrate using a knife coater in an inert atmosphere glove box. The wet substrate was heated on a pre-heated 320° C. hot plate for 3 minutes.

A second aliquot of the first ink was deposited onto the substrate using a knife coater in an inert atmosphere glove box. The wet substrate was again heated on a pre-heated 320° C. hot plate for 3 minutes.

An additional six layers of the first ink were coated and heated in a like manner for a total of eight layers, resulting in a film on the substrate.

The substrate was then heated in a pre-heated furnace at 490° C. for 10 minutes, followed by heating at 490° C. for 5 minutes while being exposed to Se vapor.

An aliquot of the second ink was deposited by knife coating onto the film on the substrate. The wet substrate was heated on a pre-heated 320° C. hot plate for 3 minutes. Following this, one additional layer of the second ink was deposited and heated in a like manner.

An aliquot of the third ink was deposited by knife coating onto the film on the substrate. The wet substrate was heated on a pre-heated 320° C. hot plate for 3 minutes. Following this, five additional layers of the third ink were deposited and heated in a like manner.

The substrate was then heated in a pre-heated furnace at 490° C. for 10 minutes, followed by heating at 490° C. for 5 minutes while being exposed to Se vapor.

The resulting thin film CIGS material on the substrate had a thickness of 1.5 μm.

SIMS analysis showed that the concentration of Ga at the substrate side of the film (back side, or Mo-side) was Ga/(In+Ga)=0.67, and the concentration of Ga at the surface of the film away from the substrate (front side of the film) was Ga/(In+Ga)=0.40.

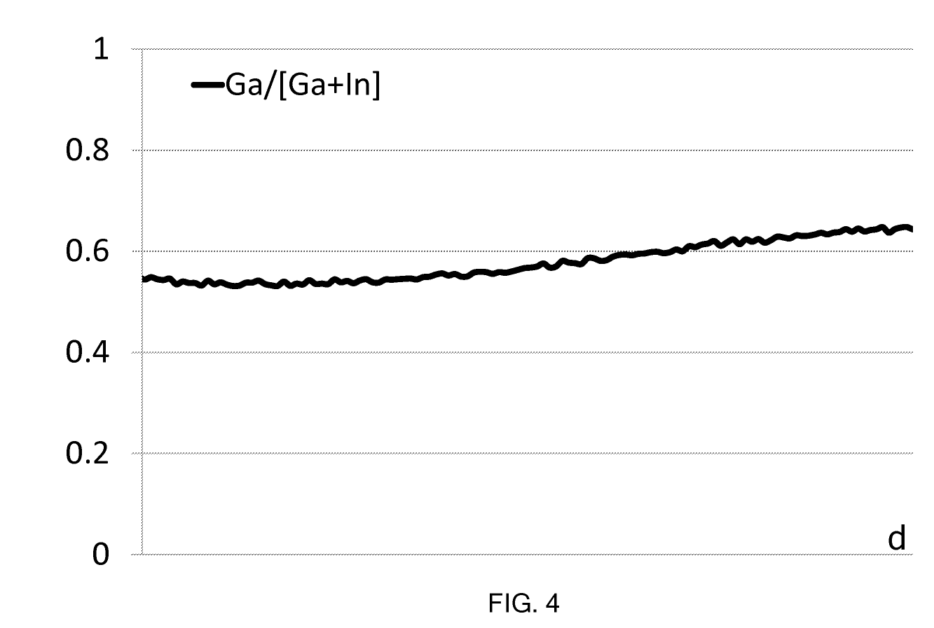

FIG. 4 shows a chart of a compositional gradient of gallium in the thin film CIGS material as measured by SIMS. The chart of FIG. 4 shows a continuous downhill gradient of gallium concentration as the distance from the substrate increases.

### Example 5

A CIGS photovoltaic absorber material was made by the following process.

A first ink was prepared containing a CIGS polymeric precursor compound having the empirical formula {Cu_{0.85}In_{0.1}Ga_{0.9}(SeBu)_{0.85}(SeⁿBu)_{3.0}} and 1.0 at % Na from NaIn(SeⁿBu)₄ by dissolving in octane under inert atmosphere to a concentration of 25% polymeric precursor content by weight. The resulting ink was filtered through a 0.2 μm PTFE syringe filter prior to use.

A second ink was prepared containing a CIGS polymeric precursor compound having the empirical formula {Cu_{0.85}In_{0.1}Ga_{0.9}(Se^{t}Bu)_{0.85}(SeⁿBu)_{3.0}} without Na by dissolving in octane to a concentration of 25% polymeric precursor content by weight. The resulting ink was filtered through a 0.2 μm PTFE syringe filter prior to use.

A third ink was prepared containing a CIGS polymeric precursor compound having the empirical formula {Cu_{0.85}In_{0.9}Ga_{0.1}(Se^{t}Bu)_{0.85}(SeⁿBu)_{3.0}} without Na by dissolving in octane to a concentration of 25% polymeric precursor content by weight. The resulting ink was filtered through a 0.2 μm PTFE syringe filter prior to use.

A fourth ink was prepared containing a CIGS polymeric precursor compound having the empirical formula {Cu_{0.85}In_{0.9}Ga_{0.1}(Se^{t}Bu)_{0.85}(SeⁿBu)_{3.0}} and 1.0 at % Na from NaIn(SeⁿBu)₄ by dissolving in octane to a concentration of 25% polymeric precursor content by weight. The resulting ink was filtered through a 0.2 μm PTFE syringe filter prior to use.

The substrate was a Mo-coated sodalime glass with a 100 nm layer of the material Cu_{1.1}In_{0.1}Ga_{0.9}Se_{2.1} on the surface on which the inks were deposited.

Ink volumes were 0.04 mL and knife coating speeds were 20 mm/sec.

An aliquot of the first ink was deposited in a single layer onto the substrate using a knife coater in an inert atmosphere glove box. The wet substrate was heated on a pre-heated 320° C. hot plate for 3 minutes.

A second aliquot of the first ink was deposited onto the substrate using a knife coater in an inert atmosphere glove box. The wet substrate was again heated on a pre-heated 320° C. hot plate for 3 minutes.

An additional four layers of the first ink were coated and heated in a like manner for a total of six layers, resulting in a film on the substrate.

An aliquot of the second ink was deposited by knife coating onto the film on the substrate. The wet substrate was heated on a pre-heated 320° C. hot plate for 3 minutes. Following this, one additional layer of the second ink was deposited and heated in a like manner.

An aliquot of the third ink was deposited by knife coating onto the film on the substrate. The wet substrate was heated on a pre-heated 320° C. hot plate for 3 minutes. Following this, one additional layer of the second ink was deposited and heated in a like manner.

An aliquot of the fourth ink was deposited by knife coating onto the film on the substrate. The wet substrate was heated on a pre-heated 320° C. hot plate for 3 minutes. Following this, five additional layers of the fourth ink were deposited and heated in a like manner.

The substrate was then heated in a pre-heated furnace at 490° C. for 10 minutes, followed by heating at 490° C. for 3 minutes while being exposed to Se vapor.

The resulting thin film CIGS material on the substrate had a thickness of 1.5 μm.

SIMS analysis showed that the concentration of Ga at the substrate side of the film (back side, or Mo-side) was Ga/(In+Ga)=0.63, and the concentration of Ga at the surface of the film away from the substrate (front side of the film) was Ga/(In+Ga)=0.52.

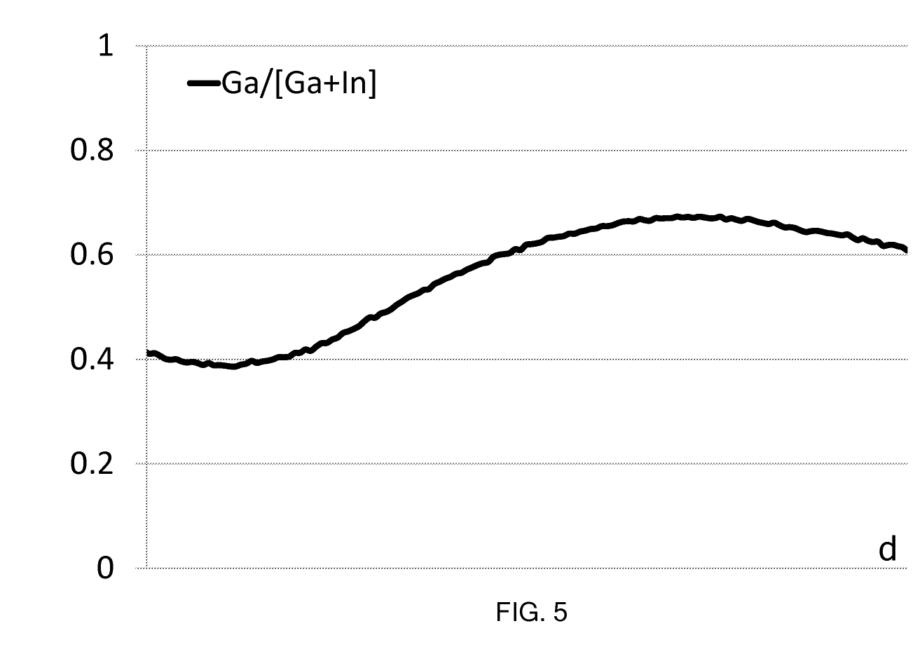

FIG. 5 shows a chart of a compositional gradient of gallium in the thin film CIGS material as measured by SIMS. The chart of FIG. 5 shows a continuous downhill gradient of gallium concentration as the distance from the substrate increases.

### Example 6

A CIGS photovoltaic absorber material was made by the following process.

A first ink was prepared containing indium and gallium molecular precursor compounds In(Se^{s}Bu)₃, Ga(SeⁿBu)₃, and Ga(Se^{s}Bu)₃, so that the ratio of In:Ga was 20:80, and the ratio of ⁿBu:^{s}Bu was 1:4, along with 1.5 at % Na from NaGa(Se^{s}Bu)₄, by dissolving in the solvent mixture 20% 2-methyltetrahydrofuran and 80% octane by weight, under inert atmosphere to a concentration of 25% precursor content by weight. The resulting ink was filtered through a 0.2 μm PTFE syringe filter prior to use.

A second ink was prepared containing indium and gallium molecular precursor compounds In(Se^{s}Bu)₃, Ga(SeⁿBu)₃, and Ga(Se^{s}Bu)₃, so that the ratio of In:Ga was 50:50, and the ratio of ⁿBu:^{s}Bu was 1:4, along with 1.5 at % Na from NaGa(Se^{s}Bu)₄, by dissolving in the solvent mixture 20% 2-methyltetrahydrofuran and 80% octane by weight, under inert atmosphere to a concentration of 50% precursor content by weight. The resulting ink was filtered through a 0.2 μm PTFE syringe filter prior to use.

A third ink was prepared containing a CIGS polymeric precursor compound having the empirical formula {Cu_{2.0}In_{0.9}Ga_{0.1}(Se^{t}Bu)_{2.0}(SeⁿBu)_{3.0}} and 0.5 at % Na from NaIn(SeⁿBu)₄ by dissolving in octane to a concentration of 50% polymeric precursor content by weight. The resulting ink was filtered through a 0.2 μm PTFE syringe filter prior to use.

A fourth ink was prepared containing a CIGS polymeric precursor compound having the empirical formula {Cu_{2.0}In_{0.5}Ga_{0.5}(SeBu)_{2.0}(SeⁿBu)_{3.0}} and 0.5 at % Na from NaIn(SeⁿBu)₄ by dissolving in octane to a concentration of 50% polymeric precursor content by weight. The resulting ink was filtered through a 0.2 μm PTFE syringe filter prior to use.

The substrate was a Mo-coated sodalime glass with a 100 nm layer of the material Cu_{1.1}In_{0.1}Ga_{0.9}Se_{2.1} on the surface on which the inks were deposited.

An 0.06 mL aliquot of the first ink was deposited in a single layer onto the substrate using a knife coater at 8 mm/sec in an inert atmosphere glove box. The wet substrate was heated on a pre-heated 150° C. hot plate for 1 minute, and a pre-heated 350° C. hot plate for 5 minutes.

An 0.06 mL aliquot of the second ink was deposited in a single layer onto the substrate using a knife coater at 11 mm/sec in an inert atmosphere glove box. The wet substrate was heated on a pre-heated 150° C. hot plate for 1 minute, and a pre-heated 350° C. hot plate for 5 minutes.

An aliquot 0.07 mL of the third ink was deposited in a single layer onto the substrate using a knife coater at 6 mm/sec in an inert atmosphere glove box. The wet substrate was heated on a pre-heated 150° C. hot plate for 1 minute, and a pre-heated 350° C. hot plate for 5 minutes.

An 0.06 mL aliquot of the fourth ink was deposited in a single layer onto the substrate using a knife coater at 7.5 mm/sec in an inert atmosphere glove box. The wet substrate was heated on a pre-heated 150° C. hot plate for 1 minute, and a pre-heated 350° C. hot plate for 5 minutes.

The substrate was then heated on a pre-heated hot plate at 530° C. for 10 minutes.

The resulting thin film photovoltaic absorber material on the substrate had a thickness of 1.2 μm.

SIMS analysis showed that the concentration of Ga at the substrate side of the film (back side, or Mo-side) was Ga/(In+Ga)=0.80, and the concentration of Ga at the surface of the film away from the substrate (front side of the film) was Ga/(In+Ga)=0.32.

FIG. 6 shows a chart of a compositional gradient of gallium in the thin film photovoltaic absorber material as measured by SIMS. The chart of FIG. 6 shows a continuous downhill gradient of gallium concentration as the distance from the substrate increases.

What is claimed is:

1. A process for making a photovoltaic absorber on a substrate comprising:
(a) providing a substrate coated with an electrical contact layer;
(b) depositing one layer of a first precursor ink onto the substrate, wherein the ink has a first concentration of a Group 13 atom;
(c) heating the substrate, thereby converting the first precursor ink to a first film material on the substrate;
(d) repeating steps (b) and (c) from zero to twenty times, thereby creating a second film material on the substrate;
(e) annealing the substrate;
(f) repeating steps (b) and (c), wherein each repetition uses an additional precursor ink having a different concentration of the Group 13 atom as any of the earlier steps, thereby creating a third film material;
(g) annealing the third film material, thereby creating a final film material on the substrate having a concentration gradient for the Group 13 atom.

2. The process of claim 1, wherein any one or more of the ink layers is substantially free from alkali ions, or substantially free from sodium ions.

3. The process of claim 1, wherein the Group 13 atom is indium, gallium, or aluminum.

4. The process of claim 1, repeating steps (f) and (g).

5. The process of claim 1, wherein the Group 13 atom is Ga and the concentrations are each a percentage that Ga atoms represent of the total of In plus Ga atoms, Ga/(In+Ga).

6. The process of claim 1, wherein the percentage that Ga atoms represent of the total of In plus Ga atoms, Ga/(In+Ga), within the gradient varies from 0% to 100%.

7. The process of claim 1, wherein at least a portion of the gradient is a step-up gradient, a step-down gradient, a step-up-hold-step-down gradient, a step-down-hold-step-up gradient, a continuous gradient, a downhill gradient, an uphill gradient, a depletion layer gradient, an enrichment layer gradient, or any combination of the foregoing.

8. The process of claim 1, wherein at least a portion of the gradient has a steepness of 20% or greater per micrometer, wherein the percentage represents the increase or decrease in the concentration that Ga atoms represent of the total of In plus Ga atoms, Ga/(In+Ga).

9. The process of claim 1, wherein any of the precursor inks contains a CIGS polymeric precursor compound.

10. The process of claim 1, wherein any of the precursor inks contains a CIS, AIS, AIGS, CAIS, CAIGS, CIGAS, AIGAS or CAIGAS polymeric precursor compound.

11. The process of claim 1, wherein any of the precursor inks contains a compound having the empirical formula M^{B}(ER)₃, where M^{B} is Al, Ga, or In, E is S or Se, and R is selected from alkyl, aryl, heteroaryl, alkenyl, amido, and silyl.

12. The process of claim 1, wherein any of the precursor inks contains a compound having the empirical formula M^{A}(ER), where M^{A} is Cu, Ag, or Au, E is S or Se, and R is selected from alkyl, aryl, heteroaryl, alkenyl, amido, and silyl.

13. The process of claim 1, wherein any of the precursor inks contains from 0.01 to 2.0 atom percent sodium ions.

14. The process of claim 1, wherein the final film material on the substrate is a CIGS photovoltaic material.

15. The process of claim 1, wherein the final film material on the substrate is a CIS, AIS, AIGS, CAIS, CAIGS, CIGAS, AIGAS or CAIGAS material.

16. The process of claim 1, wherein the heating to convert the ink to the first film material is at a temperature of from 100° C. to 450° C.

17. The process of claim 1, wherein the annealing is at a temperature of from 450° C. to 650° C., or at a temperature of from 450° C. to 650° C. in the presence of selenium vapor.

18. The process of claim 1, wherein the depositing is done by spraying, spray coating, spray deposition, spray pyrolysis, printing, screen printing, inkjet printing, ink printing, stamp printing, transfer printing, pad printing, flexographic printing, gravure printing, contact printing, reverse printing, thermal printing, lithography, electrophotographic printing, electrodepositing, electroplating, electroless plating, bath deposition, coating, wet coating, dip coating spin coating, knife coating, roller coating, rod coating, slot die coating, meyerbar coating, lip direct coating, capillary coating, liquid deposition, solution deposition, layer-by-layer deposition, spin casting, solution casting, or combinations of any of the forgoing.

19. The process of claim 1, wherein the substrate is selected from the group of a semiconductor, a doped semiconductor, silicon, gallium arsenide, insulators, glass, molybdenum glass, silicon dioxide, titanium dioxide, zinc oxide, silicon nitride, a metal, a metal foil, molybdenum, aluminum, beryllium, cadmium, cerium, chromium, cobalt, copper, gallium, gold, lead, manganese, molybdenum, nickel, palladium, platinum, rhenium, rhodium, silver, stainless steel, steel, iron, strontium, tin, titanium, tungsten, zinc, zirconium, a metal alloy, a metal silicide, a metal carbide, a polymer, a plastic, a conductive polymer, a copolymer, a polymer blend, a polyethylene terephthalate, a polycarbonate, a polyester, a polyester film, a mylar, a polyvinyl fluoride, polyvinylidene fluoride, a polyethylene, a polyetherimide, a polyethersulfone, a polyetherketone, a polyimide, a polyvinylchloride, an acrylonitrile butadiene styrene polymer, a silicone, an epoxy, and combinations of any of the forgoing.

20. A photovoltaic absorber made by the process of claim 1.

21. A process for making a photovoltaic absorber layer on a substrate comprising:
(a) providing a substrate;
(b) forming a layer of a first material on the substrate, wherein the first material has a first concentration of a Group 13 atom and the first material contains alkali ions;
(c) forming a layer of a second material onto the first material, wherein the second material has a second concentration of a Group 13 atom that is the same or different from the first concentration, wherein the second material is substantially free from alkali ions.

22. The process of claim 21, wherein steps (b) and/or (c) are repeated one or more times in any order, wherein the additional layers have a concentration of the Group 13 the same or different as any of the previous layers.

23. The process of claim 21, wherein steps (b) and/or (c) are repeated one or more times in any order and any of the layers are annealed after being formed.

24. The process of claim 21, wherein steps (b) and (c) are repeated one or more times in any order, thereby forming two or more sodium-free layers.

25. The process of claim 21, wherein the first material is annealed before step (c).

26. The process of claim 21, wherein the second material is annealed after being formed.

27. The process of claim 21, wherein the Group 13 atom is indium, gallium, or aluminum.

28. The process of claim 21, wherein the alkali ions are sodium ions at a concentration of from 0.01 to 2.0 atom percent.

29. The process of claim 21, wherein the Group 13 atom is Ga and the concentrations are each a percentage that Ga atoms represent of the total of In plus Ga atoms, Ga/(In+Ga).

30. The process of claim 21, wherein at least a portion of the gradient is a step-up gradient, a step-down gradient, a step-up-hold-step-down gradient, a step-down-hold-step-up gradient, a continuous gradient, a downhill gradient, an uphill gradient, a depletion layer gradient, an enrichment layer gradient, or any combination of the foregoing.

31. The process of claim 21, wherein the Group 13 atom is Ga, the first, second and third materials contain In and Ga and not Al, and wherein at least a portion of the gradient is a step-up-hold-step-down or enrichment layer gradient in the concentration that Ga atoms represent of the total of In plus Ga atoms, Ga/(In+Ga).

32. The process of claim 21, wherein at least a portion of the gradient has a steepness of 20% or greater per micrometer, wherein the percentage represents the increase or decrease in the concentration that Ga atoms represent of the total of In plus Ga atoms, Ga/(In+Ga).

33. The process of claim 21, wherein the photovoltaic absorber material on the substrate is a CIGS photovoltaic material.

34. The process of claim 21, wherein the photovoltaic absorber material on the substrate is a CIS, AIS, AIGS, CAIS, CAIGS, CIGAS, AIGAS or CAIGAS material.

35. The process of claim 21, wherein any of the layers is annealed in the presence of selenium vapor.

36. The process of claim 21, wherein any one of the layers is formed by depositing an ink containing one or more polymeric precursor compounds.

37. The process of claim 21, wherein any one of the layers is formed by depositing an ink containing one or more compounds having the formula M^{B}(ER)₃, wherein M^{B} is In, Ga or Al, E is S or Se, and R is selected from alkyl, aryl, heteroaryl, alkenyl, amido, and silyl.

38. The process of claim 21, wherein any one of the layers is formed by depositing an ink containing one or more compounds having the formula M^{A}(ER), wherein M^{A} is Cu or Ag, E is S or Se, and R is selected from alkyl, aryl, heteroaryl, alkenyl, amido, and silyl.

39. The process of claim 21, wherein any one of the layers is formed by chemical vapor deposition, metal-organic chemical vapor deposition, plasma enhanced chemical vapor deposition, atomic layer deposition, plasma-enhanced atomic layer deposition, sputtering, RF sputtering, DC sputtering, magnetron sputtering, evaporation, co-evaporation, electron beam evaporation, laser ablation, or any combination of the foregoing.

40. The process of claim 21, wherein any of the layers is formed by spraying, spray coating, spray deposition, spray pyrolysis, printing, screen printing, inkjet printing, ink printing, stamp printing, transfer printing, pad printing, flexographic printing, gravure printing, contact printing, reverse printing, thermal printing, lithography, electrophotographic printing, electrodepositing, electroplating, electroless plating, bath deposition, coating, wet coating, dip coating spin coating, knife coating, roller coating, rod coating, slot die coating, meyerbar coating, lip direct coating, capillary coating, liquid deposition, solution deposition, layer-by-layer deposition, spin casting, solution casting, or combinations of any of the forgoing.

41. The process of claim 21, wherein the substrate is selected from the group of a semiconductor, a doped semiconductor, silicon, gallium arsenide, insulators, glass, molybdenum glass, silicon dioxide, titanium dioxide, zinc oxide, silicon nitride, a metal, a metal foil, molybdenum, aluminum, beryllium, cadmium, cerium, chromium, cobalt, copper, gallium, gold, lead, manganese, molybdenum, nickel, palladium, platinum, rhenium, rhodium, silver, stainless steel, steel, iron, strontium, tin, titanium, tungsten, zinc, zirconium, a metal alloy, a metal silicide, a metal carbide, a polymer, a plastic, a conductive polymer, a copolymer, a polymer blend, a polyethylene terephthalate, a polycarbonate, a polyester, a polyester film, a mylar, a polyvinyl fluoride, polyvinylidene fluoride, a polyethylene, a polyetherimide, a polyethersulfone, a polyetherketone, a polyimide, a polyvinylchloride, an acrylonitrile butadiene styrene polymer, a silicone, an epoxy, and combinations of any of the forgoing.

42. A photovoltaic absorber made by the process of claim 21.

43. A photovoltaic absorber comprising a thin film material on a substrate, wherein at least a portion of the thin film material has a gradient of the concentration of a Group 13 atom in a direction substantially normal to the substrate.

44. The photovoltaic absorber of claim 43, wherein the material is a CIGS material.

45. The photovoltaic absorber of claim 43, wherein the material is a CIS, AIS, AIGS, CAIS, CAIGS, CIGAS, AIGAS or CAIGAS material.

46. The photovoltaic absorber of claim 43, wherein the Group 13 atom is indium, gallium, or aluminum.

47. The photovoltaic absorber of claim 43, wherein the Group 13 atom is Ga, the material contains In and Ga and not Al, and the concentrations are each a percentage that Ga atoms represent of the total of In plus Ga atoms, Ga/(In+Ga).

48. The photovoltaic absorber of claim 43, wherein at least a portion of the gradient is a step-up gradient, a step-down gradient, a step-up-hold-step-down gradient, a step-down-hold-step-up gradient, a continuous gradient, a downhill gradient, an uphill gradient, a depletion layer gradient, an enrichment layer gradient, or any combination of the foregoing.

49. The photovoltaic absorber of claim 43, wherein the Group 13 atom is Ga, the material contains In and Ga and not Al, and wherein at least a portion of the gradient is a step-up-hold-step-down or enrichment layer gradient in the concentration that Ga atoms represent of the total of In plus Ga atoms, Ga/(In+Ga).

50. The photovoltaic absorber of claim 43, wherein at least a portion of the gradient has a steepness of 20% or greater per micrometer, wherein the percentage represents the increase or decrease in the concentration that Ga atoms represent of the total of In plus Ga atoms, Ga/(In+Ga).
